(19) United States
(12) Patent Application Publication
(10) Pub. No.: US 2026/0020328 A1
(43) Pub. Date: Jan. 15, 2026

(54) WAFER-LEVEL HYBRID BONDED RADIO FREQUENCY CIRCUIT

(71) Applicant: Qorvo US, Inc., Greensboro, NC (US)

(72) Inventors: Michael Carroll, Jamestown, NC (US); Daniel Charles Kerr, Oak Ridge, NC (US); Eric K. Bolton, Kernersville, NC (US); Chi-Hsien Chiu, High Point, NC (US); Xi Luo, High Point, NC (US)

(21) Appl. No.: 18/995,825

(22) PCT Filed: Jul. 31, 2023
(86) PCT No.: PCT/US2023/071309

§ 371 Date: Jan. 16, 2025

Related U.S. Application Data
(60) Provisional application No. 63/394,798, filed on Aug. 3, 2022.

(51) Int. Cl. H10D 84/80; H01L 23/00

(52) U.S. Cl. CPC H10D 84/817; H01L 24/08; H01L 24/80; H01L 2224/08145; H01L 2224/80895; H01L 2224/80896

(57) ABSTRACT

The present disclosure provides a method of fabricating radio frequency (RF) circuits using three-dimensional (3D), hybrid wafer-level bonded wafers. In one aspect, a first, bottom silicon-on-insulator (SOI) wafer and a second, top SOI wafer are provided. Complementary metal-oxide semiconductor processing is then performed on both the first and second SOI wafers to fabricate transistors and form RF circuits on each wafer. The second wafer is then bonded to the first wafer to electrically couple the RF circuits together. In an aspect, the 3D fabrication method enables RF circuits that are designed using transistor structures stacked in a three-dimensional (3D) folded configuration using a plurality of wafers. In one aspect, the RF circuit uses mirrored portions that are folded together during the wafer bonding process. In another aspect, the RF circuit uses asymmetric portions between the top versus bottom wafers.

### RELATED APPLICATIONS

This application claims the benefit of provisional patent application Ser. No. 63/394,798, filed Aug. 3, 2022, the disclosure of which is hereby incorporated herein by reference in its entirety.

### FIELD OF THE DISCLOSURE

The present disclosure relates to the field of integrated circuits manufacturing and in particular to a wafer-level hybrid bonding implementation of radio frequency circuits.

### BACKGROUND

There is continuous demand for improvement in die size and performance for radio frequency (RF) products. Smaller die size allows for smaller devices, faster processing speeds, and lower power consumption of RF products. Previously, RF silicon-on-insulator technology has enabled die size and performance improvement by using more advanced complementary metal oxide semiconductor factories, processes, and tools.

However, reducing the die size of RF products causes several challenges. As the size of the die is reduced, parasitic capacitance and resistance become more prominent because the components are now closer together. This can negatively affect the signal integrity, frequency response, and noise of the RF products. Reduced die sizes also suffer from less effective thermal management because there is less area for the heat generated by the RF components to be dissipated. Reduced die size requires smaller or tighter tolerances, which require more sophisticated control of the manufacturing processes. These and other impacts of reducing die size alone thus typically increase the complexity and cost of RF products. Accordingly, it would be desirable to provide alternative solutions to these and other problems caused by the reduction of die size, while sustaining the performance of RF products.

### SUMMARY

Various embodiments of the present disclosure provide a method of fabricating radio frequency (RF) circuits for an RF product using three-dimensional, hybrid wafer-level bonded wafers. In one aspect, a first, bottom silicon-on-insulator (SOI) wafer and a second, top SOI wafer are provided. Complementary metal-oxide semiconductor (CMOS) processing is then performed on both the first and second SOI wafers to fabricate transistors and to form RF circuits on each wafer. The second wafer is then bonded to the first wafer to electrically couple the RF circuits together. Using SOI wafers and bonding at the wafer level enables the smallest pitch and shortest interconnects within the RF circuits, which can significantly reduce the layout size needed for the RF circuits without compromising performance of the RF circuits. In addition, the use of CMOS processing allows the method for RF circuits to be compatible with conventional backend processes, such as metallization, passivation, packaging, etc., known for logic circuits.

In another aspect, RF circuits for an RF product are designed using transistor structures stacked in a three-dimensional (3D) folded configuration using a plurality of wafers. In one aspect, the RF circuit uses mirrored portions that are folded together during the wafer bonding process. In another aspect, the RF circuit uses asymmetric portions between the top versus bottom wafers to take advantage of the difference in final structure between the wafers. On each wafer, transistors of the RF circuit are fabricated on a two-dimensional (2D) layer of the wafer. The wafers are then bonded together so that the transistors on each wafer face opposing each other in a folded manner and are electrically coupled to form a folded RF circuit. By designing the RF circuit in this folded manner and stacking wafers in 3D, the third dimension (e.g., height) provides a further degree of freedom in which to layout the RF circuit with less space and improved performance. For example, in one aspect, two SOI wafers are stacked, which reduces area of at least one of the RF circuits significantly. Field-effect transistors (FETs) are duplicated on both SOI wafers. which allows for the FET total channel width and pitch to be reduced significantly and to still maintain performance.

In accordance with an aspect, a method of fabricating an RF product comprises: providing a first wafer; providing a first transistor on the first wafer; providing a second wafer; providing a second transistor on the second wafer; and bonding the second wafer to the first wafer to form a bonded wafer, wherein the second transistor opposes the first transistor.

In accordance with another exemplary aspect, a radio frequency (RF) product comprises a first RF circuit on a first layer of a substrate; a second RF circuit on a second layer opposing the first layer; and an interface layer between the first layer and second layer and comprising at least one via electrically connected to the first RF circuit and the second RF circuit.

Those skilled in the art will appreciate the scope of the present disclosure and realize additional aspects thereof after reading the following detailed description in association with the accompanying drawings.

### BRIEF DESCRIPTION OF THE DRAWINGS

The accompanying drawing figures incorporated in and forming a part of this specification illustrate several aspects of the disclosure and, together with the description, serve to explain the principles of the disclosure.

FIGS. 1A-1G illustrate an exemplary process flow for fabricating radio frequency (RF) circuits using three-dimensional, hybrid wafer-level bonded wafers according to the present disclosure.

FIG. 2A is a diagram showing the bottom wafer substrate according to the present disclosure.

FIG. 2B is a diagram showing the top wafer substrate according to the present disclosure.

FIG. 3 is a diagram showing the n-type field-effect transistor (n-FET) region of block 3, according to the present disclosure.

FIG. 4 is a diagram showing the n-FET region of block 4, according to the present disclosure.

FIG. 5 is a diagram showing the top wafer being flipped over and bonded to the bottom wafer according to the present disclosure.

FIGS. 6A and 6B are diagrams summarizing the hybrid bonding process according to the present disclosure according to the present disclosure.

FIG. 7 is a diagram showing the structure created after hybrid bonding, according to the present disclosure.

FIG. 8 is a diagram showing the structure after the silicon handle wafer is removed from the top wafer according to the present disclosure.

FIG. 9 is a diagram showing the addition of further layers to the backside of the top wafer to allow electrical access to the circuits on both top and bottom wafers according to the present disclosure.

FIG. 10 illustrates an RF circuit that utilizes multiple FETs stacked in series to enable larger signals typical for RF applications.

FIGS. 11A and 11B illustrate an exemplary RF circuit fabricated by the method described herein and having mirrored FET stacks provided on the top and bottom wafers that oppose each other and can be connected in a 3D folded configuration according to the present disclosure.

FIGS. 12A and 12B illustrate an alternative exemplary RF circuit fabricated by the method described herein and having opposing FET stacks of three FETs connected by being folded together in 3D but having different configurations to take advantage of differences between the top and bottom wafers according to the present disclosure.

FIGS. 13A and 13B show another exemplary RF circuit similar to FIG. 12 but having opposing FET stacks of four FETs according to the present disclosure.

FIG. 14 illustrates an exemplary layout of the RF circuit shown in FIG. 10.

FIGS. 15 and 16 show exemplary layouts side-by-side of the RF circuit shown in FIGS. 11A and 11B to 13A and 13B having opposing FET stacks that can be connected by being folded together in 3D according to the present disclosure.

FIG. 17 shows an exemplary cross-section of a structure that results from the hybrid wafer bonding process described herein according to the present disclosure.

FIGS. 18A and 18B illustrate an RF circuit that includes multiple FETs stacked in series along with enhancement circuits according to the present disclosure.

FIG. 19 illustrates an exemplary layout of the RF circuit shown in FIG. 18.

FIGS. 20A and 20B and 21A and 21B show respective RF circuits having opposing FET stacks, linearity improvement circuits, and voltage handling circuits that can be connected by being folded together in 3D, in accordance with the hybrid wafer bonding process described in the present disclosure. FIGS. 22A and 22B show exemplary layouts side-by-side of the RF circuits shown in FIGS. 20A and 20B and 21A and 21B according to the present disclosure.

FIG. 23A shows a side view of a die singulated from a single wafer.

FIG. 23B shows a side-by-side view of a die from the bottom and top wafers to illustrate a reduced layout area according to the present disclosure.

FIG. 24A shows the same view provided in FIG. 23A and is reproduced to provide a comparison to FIG. 24B.

FIG. 24B shows an exemplary layout of an RF product having RF circuits for switches fabricated using the hybrid wafer bonding process described herein and having a reduced layout area according to the present disclosure.

FIG. 25 shows an exemplary user element that includes the RF circuits including but not limited to the RF circuit schematics and layouts shown in FIGS. 11A-13B, 15 and 16, 20A-22B, 23B, and 24B.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements. these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising.” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

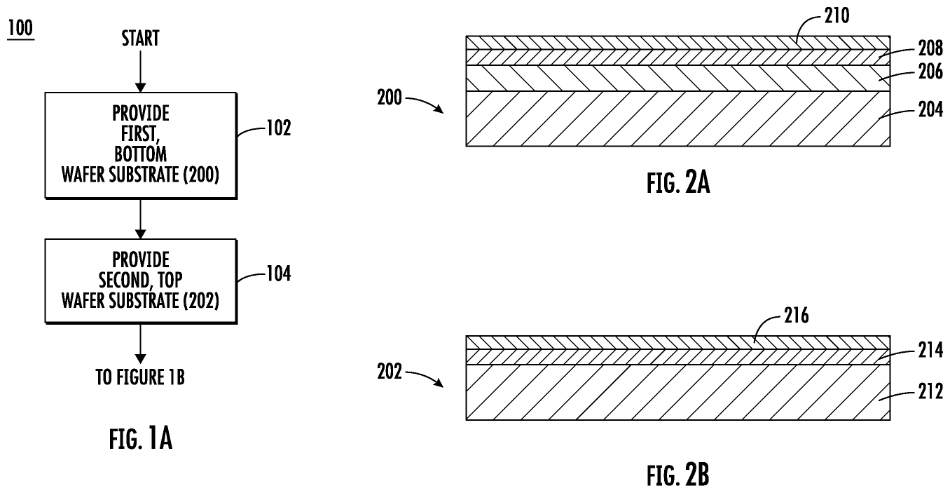

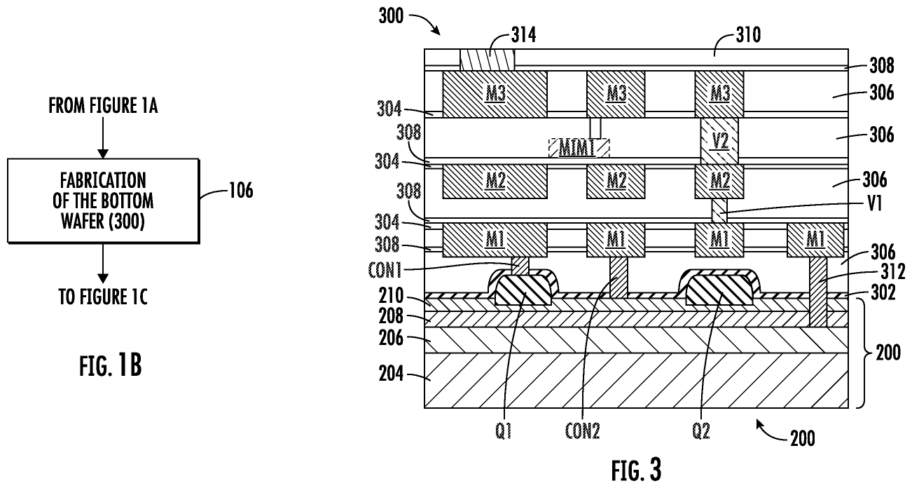

FIGS. 1A-1G illustrate a flowchart 100 that describes a fabrication process of radio frequency (RF) circuits using a three-dimensional. hybrid wafer-level bonding. FIGS. 2A and 2B to FIG. 9 illustrate an exemplary fabrication process of the RF circuits using three-dimensional, hybrid wafer-level bonding according to the process as shown in the flowchart 100. Therefore, FIGS. 1A to 1G are better understood when described jointly with illustrations of FIGS. 2A and 2B to FIG. 9.

Referring first to FIG. 1A, steps 102 and 104 of the flowchart 100 are described. In this regard, a first wafer (hereinafter referred to as a bottom wafer substrate 200) and a second wafer (hereinafter referred to as a top wafer substrate 202) are provided.

As shown in FIG. 2A, the bottom wafer substrate 200 may initially be an RF silicon-on-insulator (RFSOI) starting wafer that includes a first silicon handle wafer 204 with a high resistivity that is greater than 3000 Ω·cm, 2000 Ω·cm, or 1500 Ω·cm and a first polysilicon layer 206 having a thickness in the range of 3 μm to 1 μm, 2.5 μm to 1.5 μm, or 2.25 μm to 1.75 μm that serves as a trap-rich layer epitaxially grown for mitigation of substrate-induced distortion. Furthermore, the bottom wafer substrate 200 includes a first buried oxide (BOX) layer 208 that may have a thickness in the range of 200 A to 4000 A, 3000 A to 7000 A, or 1000 A to 10000 A and that may be as thick as 1 μm. A first top silicon device layer 210 is included as part of the bottom wafer substrate 200 and may have a thickness that is in the range of 600 A to 1500 A, 500 A to 2000 A, or 400 A to 3000 A. In certain embodiments the polysilicon (trap-rich) layer 206 could be excluded optionally to reduce cost.

FIG. 2B illustrates a cross-sectional view of a top wafer substrate 202 as used in a step 104 of the fabrication process described in the flowchart 100 of FIG. 1A. The top wafer substrate 202 may be a SOI wafer. In an embodiment, the top wafer substrate 202 is a p-type silicon wafer. The top wafer substrate 202 comprises a second silicon handle wafer 212, a second BOX layer 214, and a second top silicon device layer 216. As shown in FIG. 2B, the second silicon handle wafer 212 may have a resistivity in the range of 1 Ω·cm to 50 Ω·cm, 0.5 Ω·cm to 100 Ω·cm, or 0.1 Ω·cm to 200 Ω·cm. The second BOX layer 214 may have a thickness in the range of 2000 A to 4000 A, 1000 A to 5000 A, or 500 A to 10000 or may be as thick as 1 μm. In addition, the second top silicon device layer 216 may have a thickness of 600 A to 1500 A, 500 A to 2000 A, or 400 A to 3000 A.

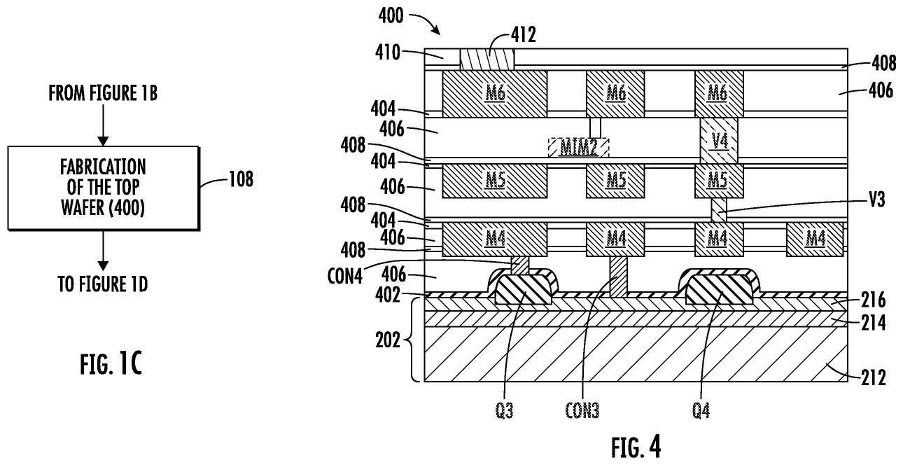

Referring now to FIG. 1B, a step 106 of the flowchart 100 is described. In this regard, FIG. 1B describes fabrication of a bottom wafer 300 as shown in FIG. 3 using a complementary metal oxide semiconductor (CMOS) process technology. FIG. 3 illustrates a cross-sectional view of the bottom wafer 300 as seen after processed using a CMOS process technology. This is done using front-end device processes and backend metallization processes that are known to those skilled in the art. All elements as shown in FIGS. 1B and 3 that were previously described in reference to FIGS. 1A, 2A, and 2B will continue to have the same reference numerals as those discussed and are not described here for brevity.

In this regard, the bottom wafer 300 may include transistors, such as, a first transistor Q1 and a second transistor Q2 that may be, for example, n-type field-effect transistors (n-FETs). While only n-FETs are shown as part of the formation of the bottom wafer 300, the scope of the present application is not so limited. Appropriately constructed p-type field-effect transistor (p-FET) and diodes. capacitors, resistors, and inductors may also be formed as part of the formation of the bottom wafer 300 that are not shown here.

A first barrier layer 302 forms over the first BOX layer 208 and the first FET Q1 and the second FET Q2. The bottom wafer 300 further includes one or more first metal layers 304 and first passivation layers 308 that are embedded in first dielectric layers 306 that provide insulation and structural surfaces for the first metal layers 304. A first contact CON1 and a second contact CON2 are fabricated and configured to provide a connection path between a first FET Q1 and a second FET Q2 and first metal interconnects M1.

Metal interconnects MN, where N is a number, such as the first metal interconnects M1, second metal interconnects M2, and third metal interconnects M3, are electrically coupled to respective ones of the first metal layers 304. A first via V1 and a second via V2 may also be provided to establish connections between different first metal layers 304 or metal interconnects MN, or a combination thereof. In addition, a first metal-insulator-metal capacitor MIM1 may also form part of the bottom wafer 300. According to various embodiments of the present disclosure, a number, thicknesses, and widths of the first metal layers 304 may vary. In an embodiment, the first metal layers 304 closer to a top surface of the bottom wafer 300 are thicker than the first metal layers 304 closer to a bottom surface of the bottom wafer 300 to be able to support higher current loads. In this regard, each of the first metal layers 304 may have a thickness that is greater 3.2 μm, 2 μm, 1.5 μm, or 1 μm.

In addition, specific to the bottom wafer 300, handle wafer contacts (HWCs) 312 may be etched through the first dielectric layer 306, the first barrier layer 302, the first top silicon device layer 210, and the first BOX layer 208 to the surface of the first silicon handle wafer 204. The HWCs 312 are used to allow charge in the first silicon handle wafer 204 to be discharged to circuit ground to prevent charge differential between the first silicon handle wafer 204 and the first metal interconnects M1. In one aspect, the HWCs 312 are located in the die seal ring area at the outer edge of the die (not shown) but may also be used in the main die area.

A first oxide layer 310 forms over a top surface of the bottom wafer 300. A first hybrid bond (HB) via 314 may form through the first oxide layer 310 to serve as an electrical connection to the bottom wafer 300. In this regard, any number of first HB vias 314 may be added. The first HB via 314 may be 1 μm to 2 μm, 0.75 μm to 3 μm, or 0.5 μm to 4 μm wide and 0.5 μm to 1 μm, 0.4 μm to 2 μm, or 0.3 μm to 3 μm thick. These dimensions may be adjusted, but in one aspect, smaller size and height for the first HB via 314 is utilized. The first HB via 314 may be created using oxide/nitride etch, copper plating, and chemical mechanical polishing (CMP) processes. The process of fabrication of the first HB via 314 may be adjusted specifically to enable the hybrid bonding process as described subsequently, such as recessing the HB via surface slightly below the surface of the first oxide layer 310 forming the topmost layer of the bottom wafer 300.

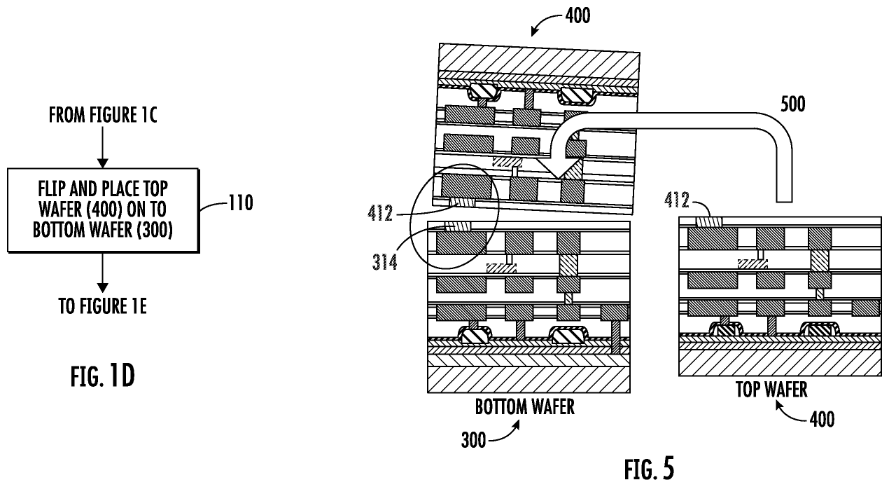

FIG. 1C shows a step 108 of the flowchart 100. In this regard, FIG. 1C describes fabrication of a top wafer 400 as shown in FIG. 4 using a complementary metal oxide semiconductor (CMOS) process technology. FIG. 4 illustrates a cross-sectional view of the top wafer 400 as seen after processed using a CMOS process technology. This is done using front-end device processes and backend metallization processes that are known to those skilled in the art. All elements as shown in FIGS. 1C and 4 that were previously described in reference to FIGS. 1A, 1B, 2A, 2B, and 3 will continue to have the same reference numerals as those discussed and are not described here for brevity.

In this regard, the top wafer 400 may include transistors, such as, a third transistor Q3 and a fourth transistor Q4 that may be, for example, n-type field-effect transistors (n-FETs). While only n-FETs are shown as part of the formation of the top wafer 400, the scope of the present application is not so limited. Appropriately constructed p-type field-effect transistor (p-FET) and diodes. capacitors, resistors, and inductors may also be formed as part of the formation of the top wafer 400 that are not shown here.

A second barrier layer 402 forms over the second BOX layer 214 and the third FET Q3 and the fourth FET Q4. The top wafer 400 further includes one or more second metal layers 404 and second passivation layers 408 that are embedded in second dielectric layers 406 that provide insulation and structural surfaces. A third contact CON3 and a fourth contact CON4 are fabricated and configured to provide a connection path between the third FET Q3 and the fourth FET Q4 and a fourth metal interconnect M4. Metal interconnects MN, where N is a number, such as the fourth metal interconnects M4. fifth metal interconnects M5, and sixth metal interconnects M6, are electrically coupled to the second metal layers 404. A third via V3 and a fourth via V4 may also be provided between the second metal layers 404 to establish connection between the fourth, fifth, or sixth metal interconnects M4, M5, or M6, and therefore the second metal layers 404. In addition, a second metal-insulator-metal capacitor MIM2 may also form part of the top wafer 400. According to various embodiments of the present disclosure, a number, thicknesses, and widths of the second metal layers 404 may vary. In an embodiment, the second metal layers 404 closer to a top surface of the top wafer 400 are thicker than the second metal layers 404 closer to a bottom surface of the bottom wafer 300 to be able to support higher current loads. In this regard, each of the second metal layers 404 may have a thickness that is greater 3.2 μm, 2 μm, 1.5 μm, or 1 μm.

A second oxide layer 410 forms over a top surface of the top wafer 400. A second hybrid bond (HB) via 412 may form through the second oxide layer 410 to serve as an electrical connection to the top wafer 400. In this regard, any number of second HB vias 412 may be added. The second HB via 412 may be 1 μm to 2 μm, 0.75 μm to 3 μm, or 0.5 μm to 4 μm wide, and 0.5 μm to 1 μm, 0.4 μm to 2 μm, or 0.3 μm to 3 μm thick. These dimensions may be adjusted, but in one aspect, smaller size and height for the second HB via 412 is utilized. The second HB via 412 may be created using oxide/nitride etch, copper plating, and chemical mechanical polishing (CMP) processes. The process of fabrication of the second HB via 412 may be adjusted specifically to enable the hybrid bonding process as described subsequently, such as recessing the second HB via 412 surface slightly below the surface of the second oxide layer 410 forming the topmost layer of the top wafer 400.

It is important to note that the structure and design of the bottom wafer 300 and the top wafer 400 as discussed above are only exemplary, and the subject matter of the present disclosure is not necessarily limited to these examples.

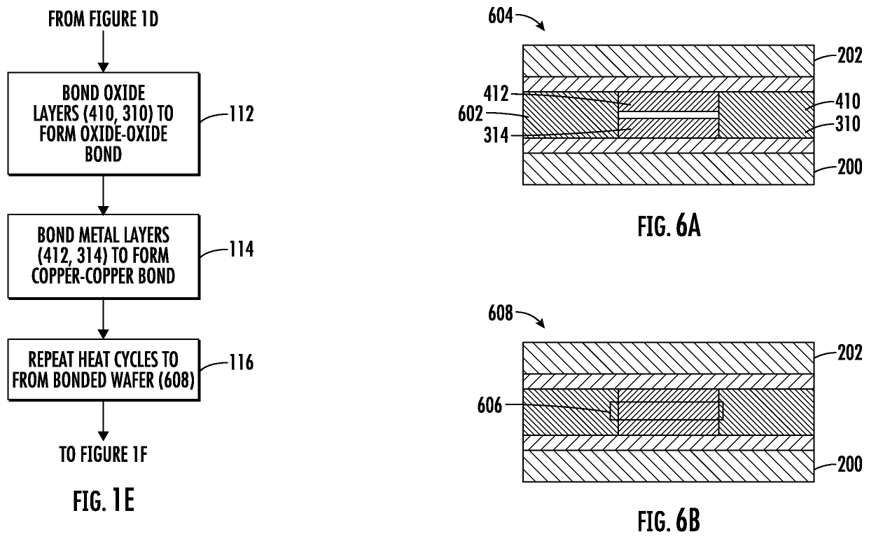

FIG. 1D shows a step 110 of the flow chart 100. In this regard, FIG. 1D describes placing the top wafer 400 as shown in FIG. 4 over the bottom wafer 300 as shown in FIG. 3. FIG. 5 illustrates a cross-sectional view of the top wafer 400 as shown in FIG. 4 as seen placed over the bottom wafer 300 as shown in FIG. 3. All elements as shown in FIGS. 1D and 5 that were previously described in reference to FIGS. 1A to 1C and FIGS. 2 to 4 will continue to have the same reference numerals as those discussed and are not described here for brevity.

In this regard, the top wafer 400 is vertically flipped and placed on and over a top surface of the bottom wafer 300 as part of a process 500. The location of the first HB via 314 of the bottom wafer 300 and the second HB via 412 of the top wafer 400 are aligned such that they form contact and electrically couple upon placement of a top surface of the top wafer 400 over a top surface of the bottom wafer 300. The top and bottom wafers 400 and 300 may be planarized to be flat enough so that when they are brought together, a full connection of top surfaces of the top and bottom wafers 400 and 300 is reached. Planarization may be done by a chemical mechanical polishing (CMP). The second and first HB vias 412 and 314 on the top and bottom wafers 400 and 300 are aligned together using a wafer alignment process 502 to provide an electrical connection between the FETs.

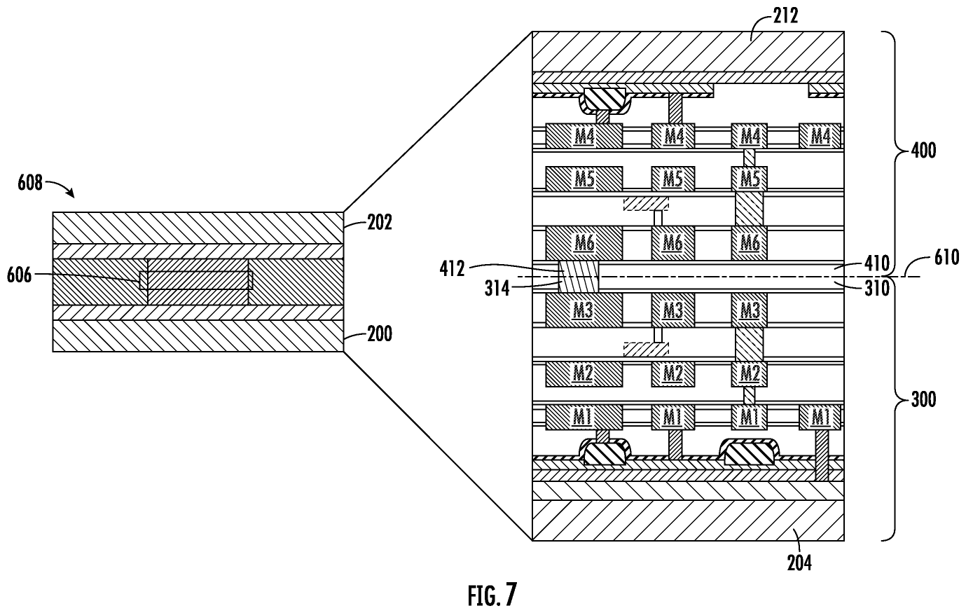

FIG. 1E shows steps 112, 114, and 116 of the flowchart 100. In this regard, FIG. 1E describes a formation of an oxide-oxide bond as shown in FIG. 6A and a formation of a copper-copper bond as shown in FIG. 6B. All elements as shown in FIGS. 1E, 6A, and 6B that were previously described in reference to FIGS. 1A to 1D and FIGS. 2 to 5 will continue to have the same reference numerals as those discussed and are not described here for brevity.

FIG. 6A shows the top wafer 400 having the top wafer substrate 202 and the bottom wafer 300 having the bottom wafer substrate 200 as seen after a top surface of the top wafer 400 is bonded to a top surface of the bottom wafer 300 using, for example, a hybrid oxide-copper bonding process. In this regard, the top wafer 400 is vertically flipped and place over the top surface of the bottom wafer 300. the first and the second HB vias 314 and 412 are aligned, and a heating cycle is performed. The heating cycle enables a formation of an oxide-oxide bond 602 between the first oxide layer 310 and second oxide layer 410.

FIG. 6B shows the top wafer 400 having the top wafer substrate 202 and the bottom wafer 300 having the bottom wafer substrate 200 as seen after the heating cycle forms a copper-copper bond 606 between the third metal interconnect M3 and the sixth metal interconnect M6 and between the first HB via 314 and the second HB via 412 to create a bonded wafer 608. The heating cycle enables a formation of the copper-copper bond 606 between the metal interconnects M3 and M6 and between HB vias 314 and 412. In this manner, the bottom wafer 300 and top wafer 400 form the bonded wafer 608. It is to be noted that repeated heating cycles may be performed, while not necessary, to further compress the copper-copper metal bonds and joints.

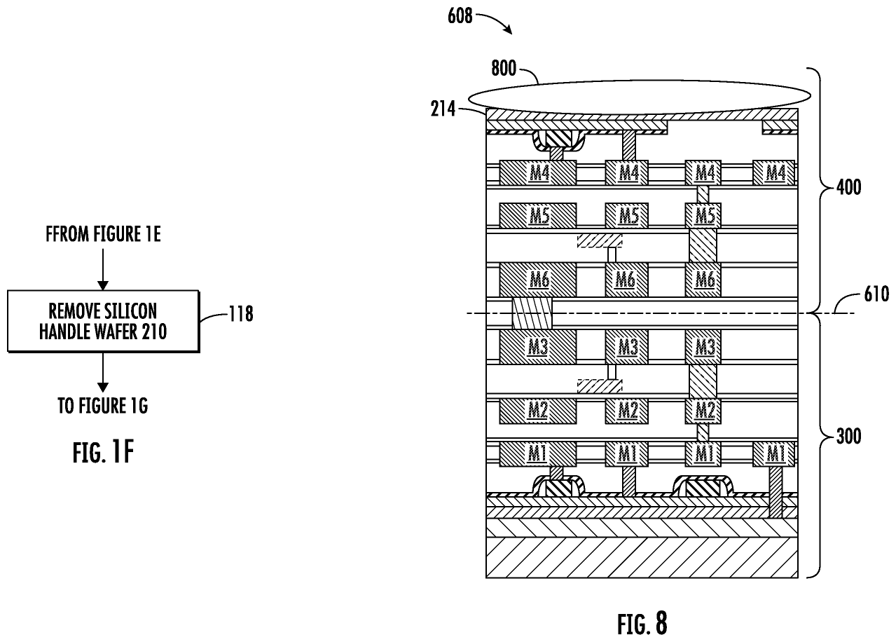

FIG. 7 shows an expanded view of the bonded wafer 608 as seen after a top surface of the top wafer 400 having the top wafer substrate 202 is bonded to a top surface of the bottom wafer 300 having the bottom wafer substrate 200. All elements as shown in FIG. 7 that were previously described in reference to FIGS. 1A to 1D and FIGS. 2 to 6A and 6B will continue to have the same reference numerals as those discussed and are not described here for brevity.

In various embodiments, semiconductor devices, circuit blocks, or interconnects of the top wafer 400 and the bottom wafer 300 may differ or be configured to perform different functions. Alternatively or in addition, semiconductor devices, circuit blocks, or interconnects of the top wafer 400 and the bottom wafer 300 are connected in parallel using multiple HB vias, such as the first HB via 314 and the second HB via 412, to serve as two FETs that are 3D stacked and connected by being folded over each other. This is particularly advantageous as it improves the performance while reducing the size of the bonded wafer 608 configured to perform a circuit function. It is noted that FIG. 7 is a simplified diagram to show the layer structure of the bonded wafer 608 and is not intended to illustrate a circuit function. In this regard, the design of the top wafer 400 and the bottom wafer 300 may be mirrored either during the design process or during the mask fabrication process. In other embodiments, after dicing a die from the bonded wafers 608, the HWCs 312 in the bottom wafer 300 can be part of a die seal ring at the edge of the die (not shown in FIG. 7). Generally, the die seal ring includes all metal layers stacked up as a wall of metal to prevent damage to the die during dicing/singulation and to prevent moisture ingress to the die. The first and second HB vias 314 and 412 may also be added to the die seal ring to electrically connect the top and bottom die seal rings together.

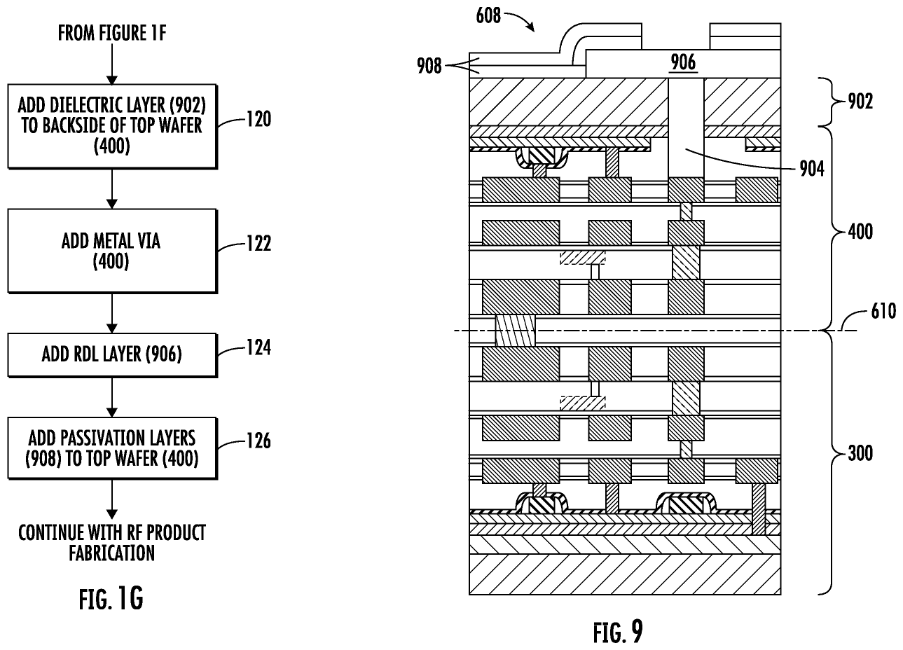

FIG. 1F shows step 118 of the flowchart 100. In this regard, FIG. 1F describes a removal of the second silicon handle wafer 212 of the top wafer 400 by a removal process 800 as shown in FIG. 8. In this regard, FIG. 8 illustrates the bonded wafer 608 as seen after the second silicon handle wafer 212 of the top wafer 400 is removed by the removal process 800. All elements as shown in FIGS. 1F and 8 that were previously described in reference to FIGS. 1A to 1E and FIGS. 2 to 7 will continue to have the same reference numerals as those discussed and are not described here for brevity.

The removal process 800 may be done through a wafer grinding process, a CMP, a chemical etching process, or the like, or a combination thereof. For example, a wafer grinding process may be used to substantially remove the second silicon handle wafer 212 followed by a CMP or a chemical etching process for removal of any remnants of the second silicon handle wafer 212. In an embodiment, the final CMP or etching process may be a process that is selective to oxides to prevent a removal of or damage to the second BOX layer 214 of the top wafer 400.

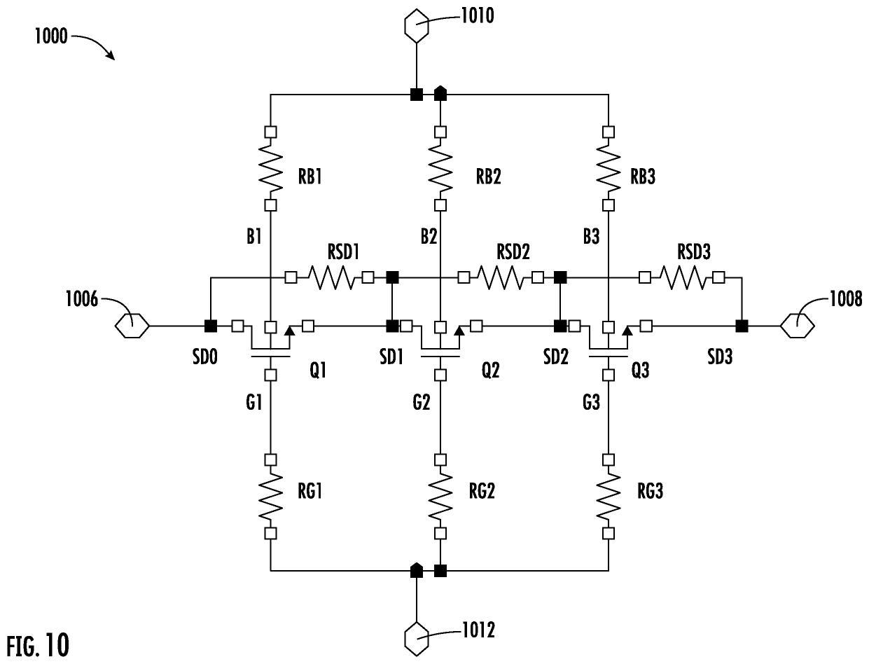

FIG. 1G shows steps 120 to 126 of the flowchart 100. In this regard, step 120 describes a formation of a third dielectric layer 902 over a bottom surface of the top wafer 400 (i.e., disposed above the second BOX layer 214) as shown in FIG. 8. Step 122 describes a formation of a backside via 904 that extends through the third dielectric layer 902, the second BOX layer 214, and the second top silicon device layer 216 to form an electrical connection with one of the metal interconnects M4, as part of the top wafer 400. Step 124 shows a formation of a backside metal redistribution layer (RDL) 906. Step 126 describes a formation of a third passivation layers 908 over a top surface of the exposed surfaces of the third dielectric layer 902 and portions of the backside RDL 906. In this manner, an opening is formed over a top surface of the backside RDL 906 such that the bonded wafer 608 is connected to other external circuitry, a signal source, a power source, or the like, or a combination thereof. In this regard, FIG. 9 illustrates the bonded wafer 608 as seen after a formation of the third dielectric layer 902, the backside via 904, the backside RDL 906, and the third passivation layers 908 over a bottom surface of the top wafer 400 and above the second BOX layer 214. All elements as shown in FIGS. 1G and 9 that were previously described in reference to FIGS. 1A to 1F and FIGS. 2 to 8 will continue to have the same reference numerals as those discussed and are not described here for brevity.

The third dielectric layer 902 may be any suitable material such as silicon nitride. Other dielectrics, such as silicon dioxide, may also be used. In an embodiment, silicon nitride is utilized due to its thermal conductivity, which allows heat conduction from devices on the top wafer 400, e.g., flip-chip packaging. The third dielectric layer 902 may have a thickness that range of 0.1 μm to 10 μm, 0.05 μm to 50 μm, or 0.01 μm to 100 μm. A thicker third dielectric layer 902 may be used to provide less electrical coupling between the backside metal in the metal interconnect M6 and the RF circuitry.

Next, the backside via 904 is formed through the third dielectric layer 902, e.g., to the metal interconnects M4 to provide an electrical connection path. For example, an opening may be etched in the third dielectric layer 902 and metal deposited or plated to create the backside via 904. The backside via 904 may be copper, aluminum, or any other suitable material. After the backside via 904 is created, patterned backside RDL 906 is deposited. Formation of the RDL 906 may be done using either metal deposition, or the like. The patterned backside RDL 906 may be copper, aluminum, or any other suitable material. In some embodiments, the backside via 904 and the backside RDL 906 may be deposited and/or plated using a single step to reduce cost. Next, one or more third passivation layers 908, such as silicon dioxide. silicon nitride, or the like are deposited over a top surface of the exposed surfaces of the third dielectric layer 902 and portions of the backside RDL 906. In this manner, an opening is formed over a top surface of the backside RDL 906 such that wire bonds or solder bumps may form (not shown) over the bonded wafer 608. Alternatively, third passivation layers 908 are deposited over the bottom surface of the top wafer 400 followed by opening areas of the third passivation layers 908, e.g., through etching, in areas where wire bonds or solder bumps will be added.

In an embodiment, a process control monitor (PCM) electrical testing may be performed to test a performance of the bonded wafer 608 comprising the bottom wafer 300 and the top wafer 400. The PCM testing may include testing of FETs on the bottom wafer 300 and the top wafer 400, together or separately. The PCM testing may also be done with FETs on both the bottom wafer 300 and the top wafer 400 connected in parallel to reduce the PCM test structure area.

In this regard, based on the 3D RFSOI fabrication method described above, RF circuits for an RF product. such as a switch or amplifier. can be fabricated using 3D, hybrid wafer-level bonded wafers and can be laid out more efficiently. Field-effect transistors are fabricated on both SOI wafers, which allows for the FET total channel width and pitch to be reduced significantly and still maintain performance. In one aspect, the RF circuits use a stacked FET structure that can connected by being folded together in 3D through the hybrid wafer-level bonding method according to the present disclosure. By designing the RF circuit in this folded manner and stacking wafers in 3D, the third dimension (e.g., height) provides a further degree of freedom in which to lay out the RF circuit with less space and improved performance. For example, in one aspect. two SOI wafers are stacked, which reduces the area of at least one of the RF circuits significantly.

As noted previously, in one aspect, the RF circuit uses mirrored portions that are connected by being folded together in 3D during the wafer bonding process. Mirroring the RF circuit, for example, on the bottom wafer 300 and the top wafer 400 can ensure that it operates in a balanced fashion, which may be important for RF applications. In another aspect, the RF circuit uses asymmetric portions between the top versus bottom wafers to take advantage of the difference in final structure between the wafers.

In another exemplary aspect, various design techniques are disclosed to maintain the performance of the RF circuits. For example, in one aspect, nodes of the RF circuits on both the bottom wafer 300 and the top wafer 400 are electrically connected via the first and second HB vias 314 and 412 placed at specific locations to the FETs to balance their operations. This ensures that both RF circuits operate in phase with each other and maintain good voltage handling.

In another exemplary aspect, the first SOI and second SOI wafers, such as the bottom wafer 300 and the top wafer 400, may have different thermal resistance. For example. the bottom wafer 300 may remain attached to a first silicon handle wafer 204, which provides a substrate and path for thermal dissipation. Since the bottom wafer 300 is intervening, the top wafer 400 may be a greater distance from the first silicon handle wafer 204 and thus may have a greater thermal resistance. According to one exemplary aspect, different RF circuits may be provided in the bottom wafer 300 and the top wafer 400 depending on their thermal characteristics. In addition, HB vias, such as the first and second HB vias 314 and 412, and metal connections may be provided between the bottom and the top wafer substrates 200 and 202 to provide thermal pathways.

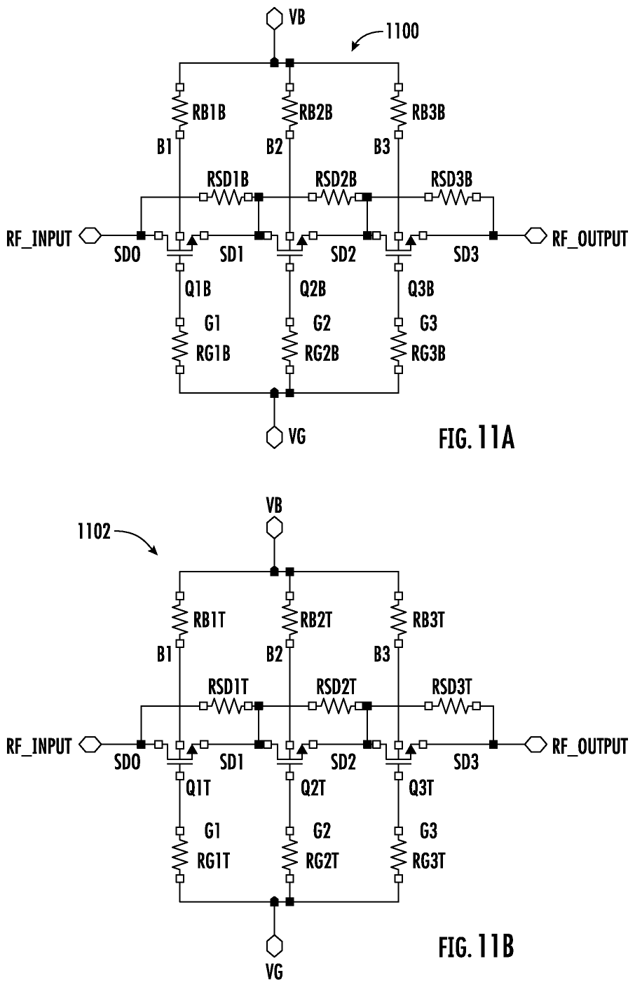

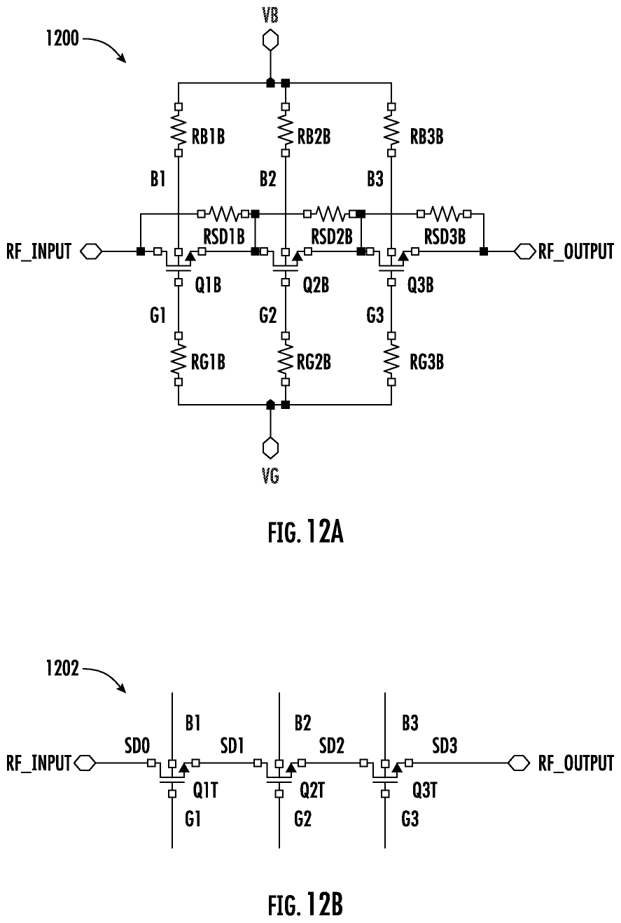

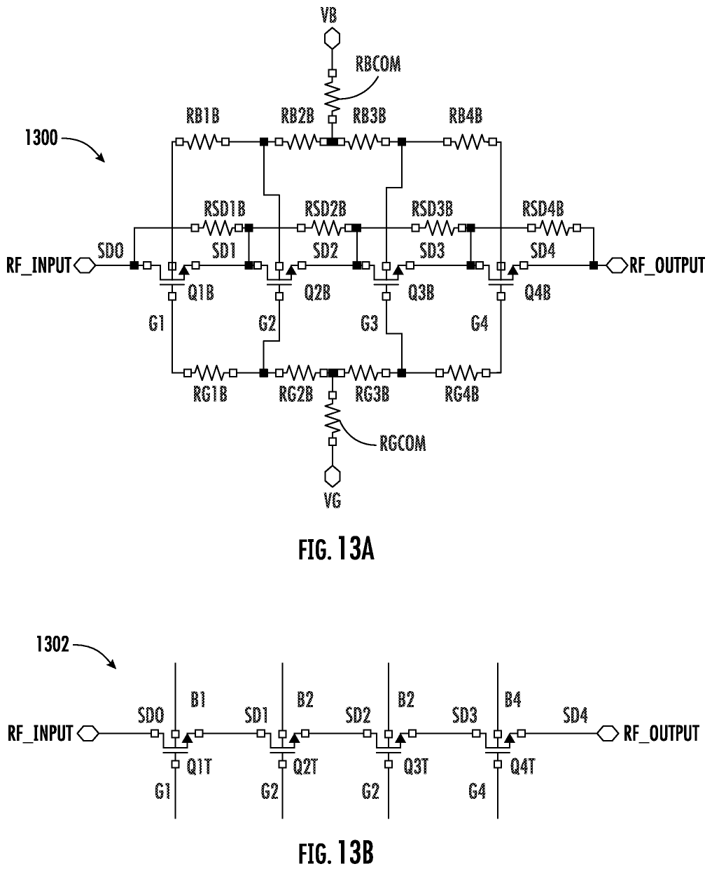

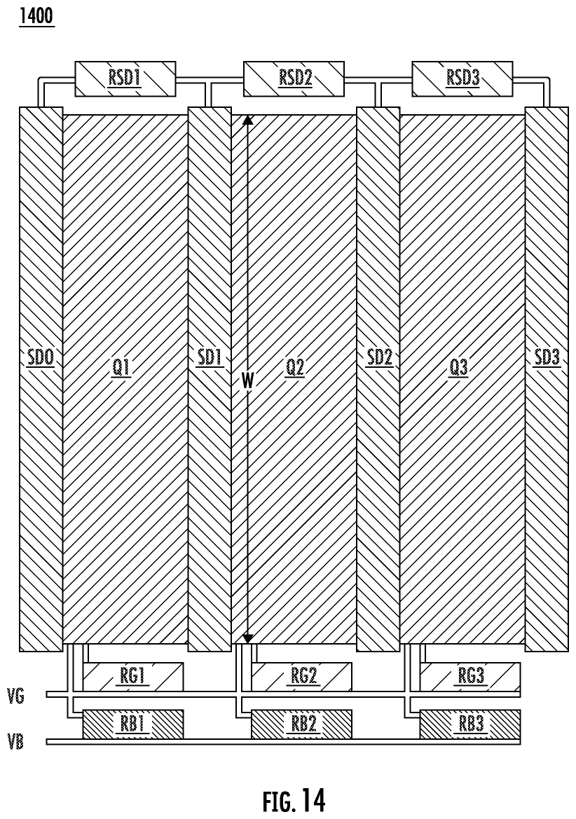

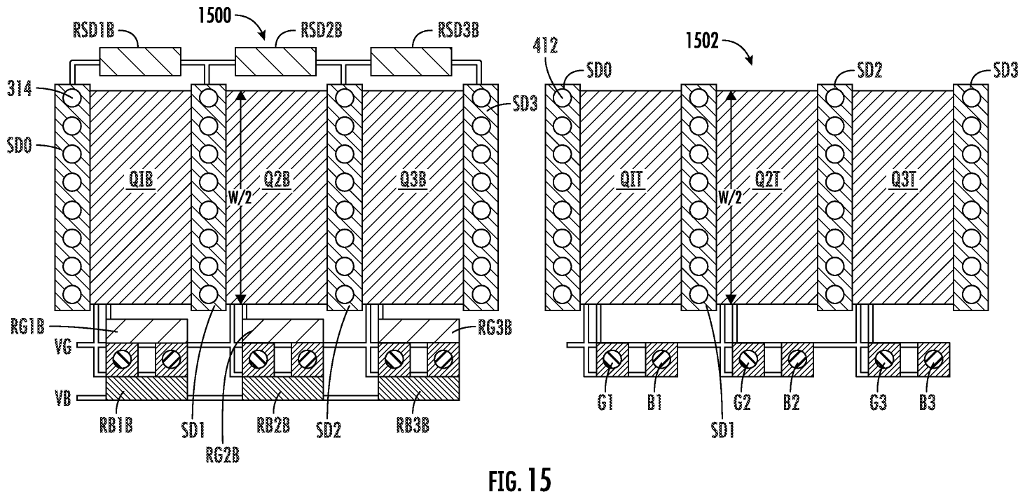

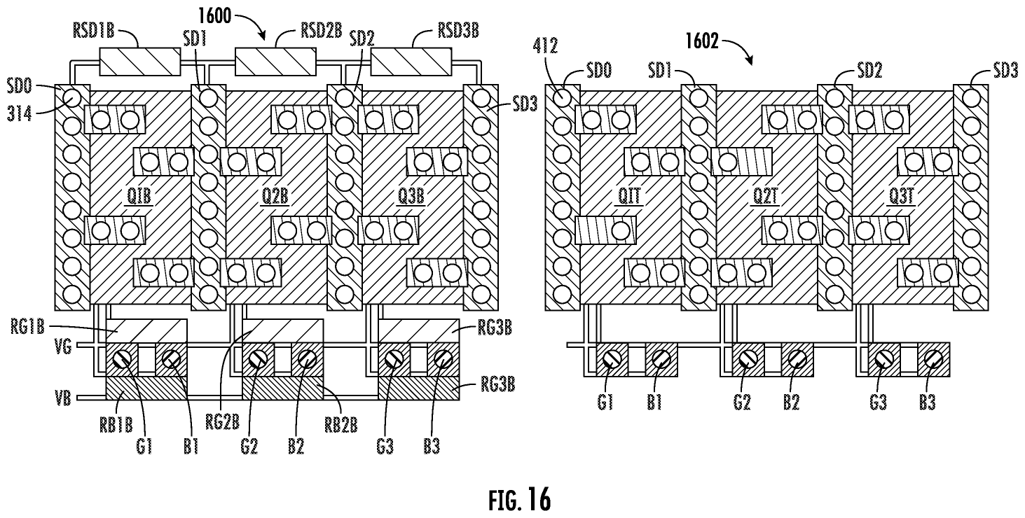

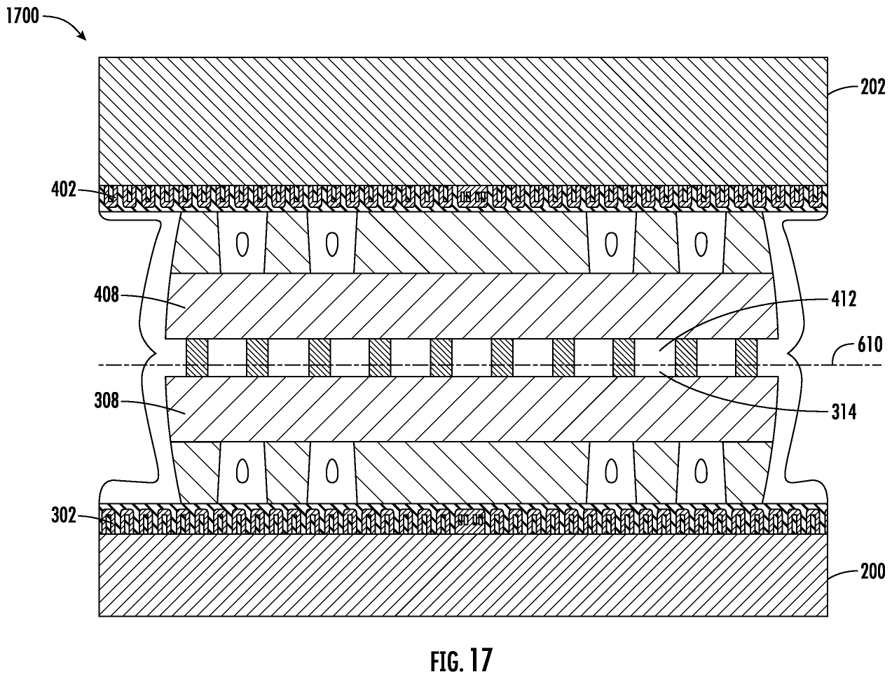

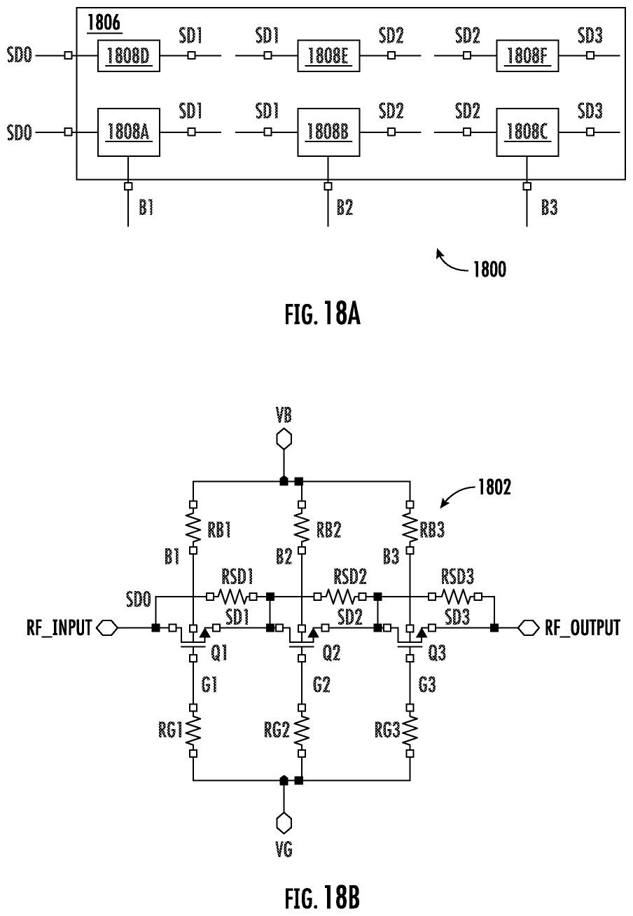

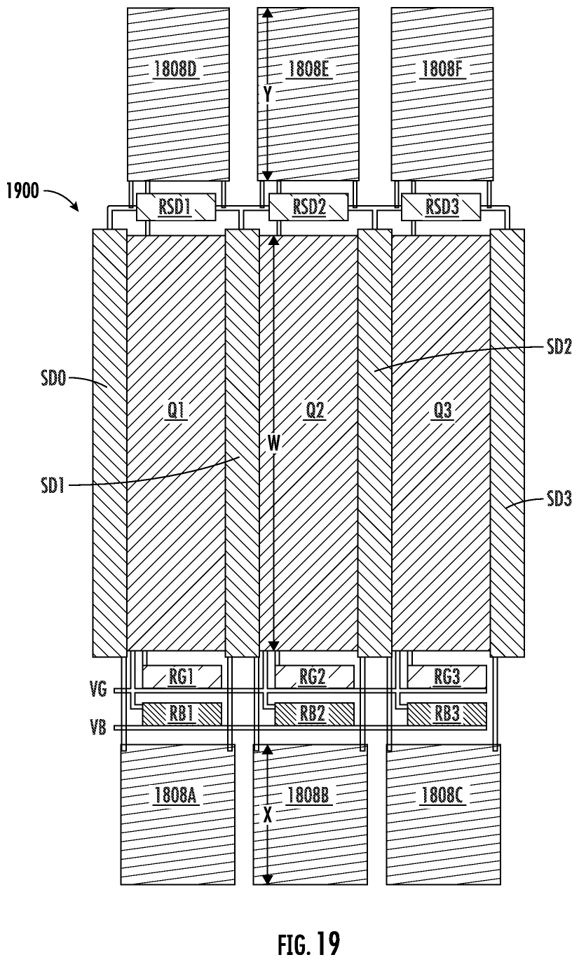

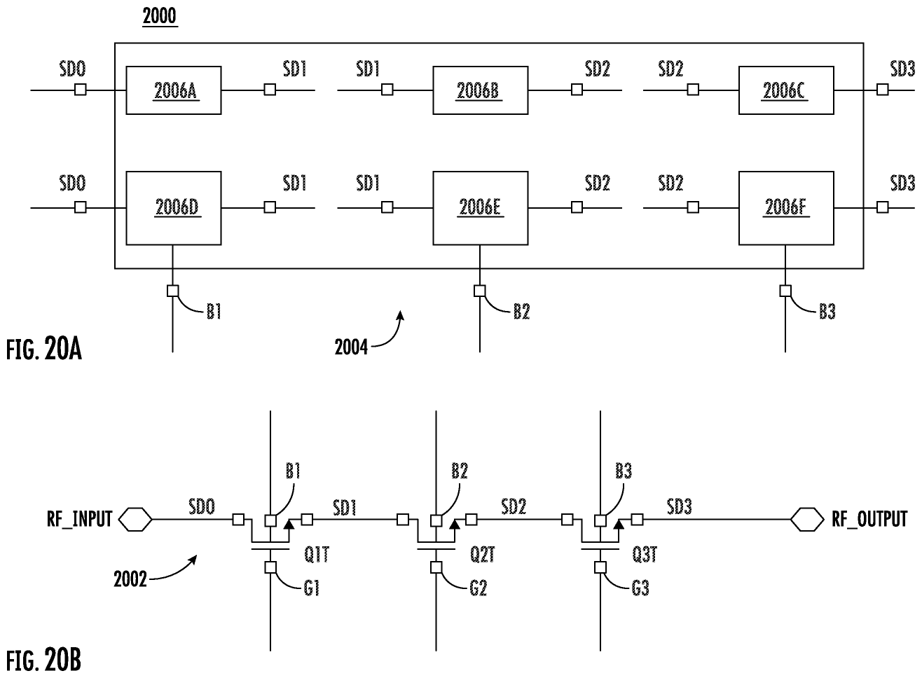

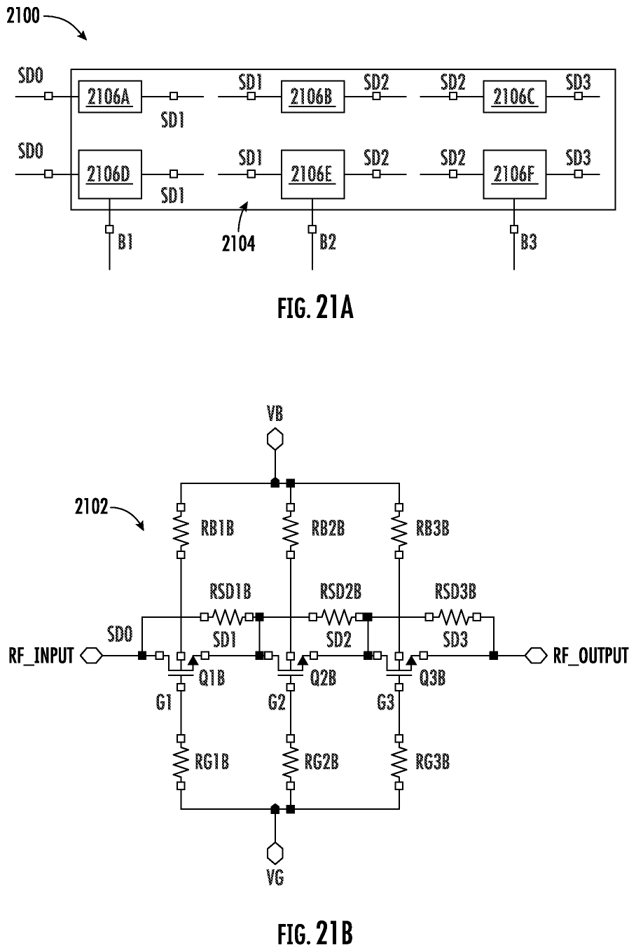

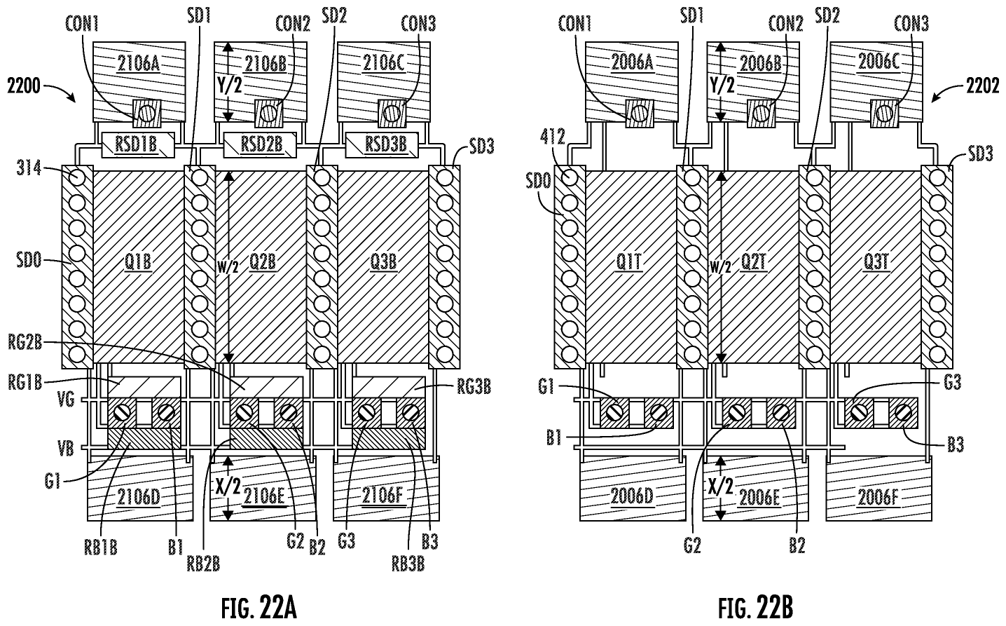

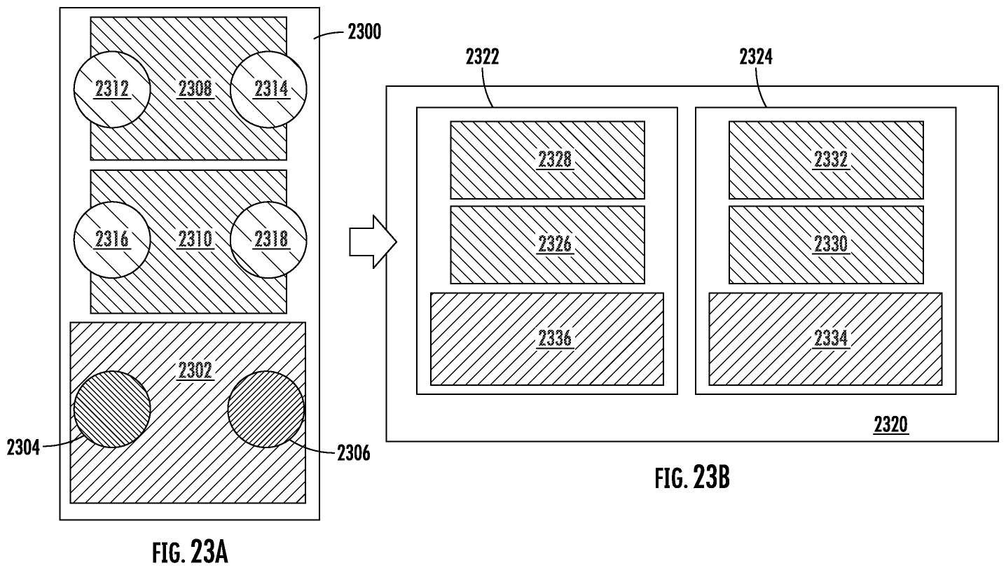

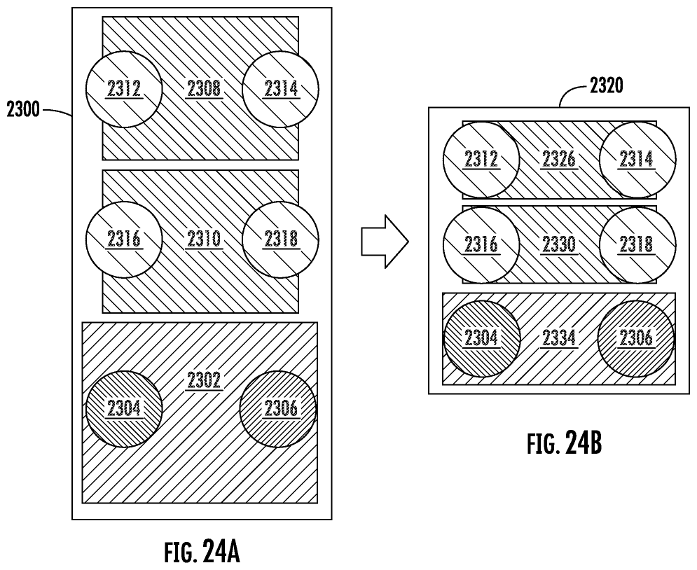

In this regard, various RF circuit schematics and layouts will now be described with reference to FIGS. 10 to 22A and 22B and FIGS. 23A, 23B, 24A, and 24B to illustrate the various aspects of the present disclosure. In view of the numerous configurations possible, a summary of the figures presented is now provided to assist in describing aspects of the present disclosure. FIG. 10 illustrates an RF circuit that utilizes multiple FETs stacked in series to enable larger signals typical for RF applications. FIGS. 11A and 11B illustrate an exemplary RF circuit fabricated by the method described herein and having mirrored FET stacks provided on the top and bottom wafers that oppose each other and can be connected in a 3D folded configuration. FIGS. 12A and 12B illustrate an alternative exemplary RF circuit fabricated by the method described herein and having opposing FET stacks of three FETs connected by being folded together in 3D configurations but having different configurations to take advantage of differences between the top and bottom wafers. FIGS. 13A and 13B show another exemplary RF circuit similar to FIGS. 12A and 12B but having a common bias resistor to feed a direct current (DC) bias into a center of the FET stack. FIG. 14 illustrates an exemplary layout of the RF circuit as shown in FIG. 10. FIG. 15 shows an exemplary layout of the RF circuit as shown in FIGS. 12A and 12B as seen in a final flipped (i.e., mirrored) orientation. FIG. 16 shows an alternative metallization arrangement of FIG. 15 that enables having more HB vias as shown in a final flipped (i.e., mirrored) orientation. FIG. 17 shows an exemplary cross-section of a structure that results from the hybrid wafer bonding process described herein. FIGS. 18A and 18B illustrate an RF circuit used for a 2D design, without bonding, and including multiple FETs stacked in series, linearity improvement circuits, and voltage handling improvement circuits. FIG. 19 illustrates an exemplary layout of the RF circuit shown in FIGS. 18A and 18B. FIGS. 20A, 20B, 21A, and 21B show respective RF circuits having opposing FET stacks, linearity improvement circuits, and voltage handling circuits that may be connected by being folded together in a 3D configuration, in accordance with the hybrid wafer bonding process described herein. FIGS. 22A and 22B show exemplary layouts side-by-side of the RF circuits shown in FIGS. 20A, 20B, 21A, and 21B. FIG. 23A shows a side view of a die diced from a single wafer and its resulting layout size. FIG. 23B shows a side-by-side of a die from the bottom and top wafers to illustrate a reduced layout size in accordance with the present disclosure. FIG. 24A shows a layout of an RF product having RF circuits for switches and a control circuit. FIG. 24B shows an exemplary layout of an RF product having RF circuits for switches that are fabricated using the hybrid wafer bonding process described herein with a reduced layout area in comparison to the layout area as shown in FIGS. 23A and 24A.

FIG. 10 shows an exemplary circuit schematic of an RF switch 1000 that may be implemented using a single wafer. All elements as shown in FIG. 10 that were previously described in reference to FIGS. 1 to 9 will continue to have the same reference numerals as those discussed and are not described here for brevity. The RF switch 1000 comprises a plurality of field-effect transistors (FETs), for example, Q1, Q2, and Q3 that are stacked in series. Nonetheless, the scope of the present disclosure is not so limited. The total number of FETs stacked in series as switches in RF switch 1000 may vary depending on the RF voltage signal desired in the RF product. In an embodiment, the total number of FETs stacked in series as switches in RF switch 1000 may range from 1 to 50 or more than 50 depending on the RF voltage signal desired in the RF product. Each of the FETs Q1, Q2, and Q3 comprises a respective gate terminal G1, G2, and G3 and a respective source terminal, drain terminal, and body terminal that are not shown for the simplicity of illustration. In this regard, a source terminal of the first FET Q1 connects to a drain terminal of the second FET Q2 to form a first source-drain node SD1. Furthermore, a source terminal of the second FET Q2 connects to a drain terminal of the third FET Q3 to form a second source-drain node SD2. In this regard, the drain node of the first FET Q1 connects to an input node SD0 and the source node of the third FET Q3 connects to an output node SD3. In this manner, a first source-drain resistor RSD1 is coupled between the input node SD0 and the first source-drain SD1. A second source-drain resistor RSD2 is coupled between and first source-drain SD1 and the second source-drain SD2. A third source-drain resistor RSD3 is coupled between and second source-drain SD2 and the output node SD3.

The RF switch 1000 is provided between an RF_INPUT terminal 1006 and an RF_OUTPUT terminal 1008 wherein the RF_INPUT terminal 1006 connects to the first input node SD0 and the RF_OUTPUT terminal 1008 connects to the output node SD3. In this manner, the RF switch 1000 utilizes FETs Q1, Q2, and Q3 in series so as to enable handling of RF voltage signals with high values that may damage or degrade a performance of a single FET.

In an embodiment, the RF voltage signals at RF_INPUT terminal 1006 and RF_OUTPUT terminal 1008 are divided substantially equal across the FETs Q1, Q2, and Q3. It may be desirable to minimize parasitic capacitances between the drain, source, body, and gate terminals of the FETs Q1, Q2, and Q3, and other parts of the RF switch 1000 circuit that may alter the substantially equal division of the RF voltage signals across the FETs Q1, Q2, and Q3. Accordingly, as previously described in reference to FIGS. 2 to 9, RF chips fabricated and manufactured using RFSOI processes may have a first silicon handle wafer 204 as part of the bottom wafer substrate 200 of the bottom wafer 300 that has a high resistivity. Furthermore, the bottom wafer substrate 200 may comprise a first polysilicon layer 206 that minimizes depletion/inversion effects at the first BOX layer 208. In addition, metal conductors are formed away from the FETs Q1, Q2, Q3 having reduced lengths.

Gate resistors RG1, RG2, and RG3 are connected between gate terminals G1, G2, and G3 and a DC supply voltage terminal 1012 having a gate voltage signal VG. Furthermore, body resistors RB1, RB2, and RB3 are connected between body terminals B1, B2, and B3 and a body voltage terminal 1010 having a body voltage signal VB. The value of the gate resistors RG1, RG2, RG3 and body resistors RB1, RB2, RB3 may vary depending on the application in the range of 10 Ω to 1000 kΩ, 500 to 500 kΩ, or 100 Ω and 100 kΩ. In this manner, each of the FETs Q1, Q2, and Q3 in the FET stack are supplied with a DC bias from the DC supply voltage terminal 1012 and the body voltage terminal 1010.

FIG. 11A illustrates an exemplary schematic of a first RF circuit 1100 implemented in the bottom wafer 300 as described in reference to FIGS. 1 to 9. FIG. 11B illustrates an exemplary schematic of a second RF circuit 1102 implemented in the top wafer 400 as described in reference to FIGS. 1 to 9. All elements as shown in FIGS. 11A and 11B that were previously described in reference to FIGS. 1 to 10 will continue to have the same reference numerals as those discussed and are not described here for brevity.

The first RF circuit 1100 and the second RF circuit 1102 as discussed in reference to FIGS. 11A and 11B are substantially similar to the RF switch 1000 as described in reference to FIG. 10. To minimize parasitic capacitances associated with the first RF circuit 1100 and the second RF circuit 1102 and to avoid metal conductors of significant lengths as part of a fabrication process. the first RF circuit 1100 and the second RF circuit 1102 are designed to be mirror copies of one another. However, each of the first RF circuit 1100 and the second RF circuit 1102 is implemented on a different wafer, such as the bottom wafer 300 and the top wafer 400, respectively, which are bonded together using the RF-SOI hybrid wafer bonding methods described above. In this manner, the first and second RF circuits 1100 and 1102 are connected in parallel to form an RF switch. In doing so, RF_INPUT terminals 1006 of the first RF circuit 1100 and the second RF circuit 1102 are connected to one another to form a single RF_INPUT terminal. Furthermore, RF_OUTPUT terminals 1008 of the first RF circuit 1100 and the second RF circuit 1102 are connected to one another to form a single RF_OUTPUT terminal.

As shown, each of the first RF circuit 1100 and the second RF circuit 1102 comprises a stack of FETs Q1B, Q2B, and Q3B and Q1T, Q2T, and Q3T, respectively. After bonding of bottom wafer 300 comprising the first RF circuit 1100 and the top wafer 400 comprising the second RF circuit 1102, the first RF circuit 1100 and the second RF circuit 1102 are connected as the top wafer 400 is vertically flipped and placed over the bottom wafer 300 as previously illustrated and described in reference to FIG. 5. In this regard, the total number of FETs is doubled while reducing the layout area. By having the FETs on both the bottom wafer 300 and the top wafer 400, a total channel width associated with each FET Q1B, Q2B, and Q3B and Q1T, Q2T, and Q3T may be reduced by 30%, 40%, and 50% while maintaining a same overall electrical performance. In this regard, the total 2D area associated with the first RF circuit 1100 and the second RF circuit 1102 as bonded using the bottom wafer 300 and the top wafer 400 may be reduced by approximately 30%, 40%, or 50%, enabling a more compact die.

Gate, body, and source-drain resistors RG1B, RG2B, RG3B, RB1B, RB2B, RB3B, RSD1B, RSD2B, and RSD3B of the first RF circuit 1100 and gate, body, and source-drain resistors RG1T, RG2T. RG3T, RB1T, RB2T. RB3T, RSD1T, RSD2T, and RSD3T of the second RF circuit 1102 are connected as previously illustrated and described in reference to FIG. 10 and are not described herein. Nodes RF_INPUT, RF_OUTPUT, VG, VB, SD0, SD1, SD2, SD3, G1, G2, G3, B1, B2, and B3 are common in the first RF circuit 1100 and the second RF circuit 1102 and were previously described in reference to FIG. 10 and are not described here for brevity. In this regard, the nodes RF_INPUT, RF_OUTPUT, VG, VB, SD0, SD1, SD2, SD3, G1, G2, G3, B1, B2, and B3 of the first RF circuit 1100 and the second RF circuit 1102 may be electrically coupled using one or more HB vias, such as HB vias 314, 412, which are electrically connected as the bottom wafer 300 and the top wafer 400 are bonded in accordance with the hybrid wafer bonding method described in conjunction with FIGS. 5 to 9. In yet another aspect, the RF signal carried by RF_INPUT and RF_OUTPUT is maintained in phase with a safe and a high level of voltage handling as the RF signal is divided nearly equally across the stacks of FETs Q1B, Q2B, and Q3B and Q1T, Q2T, and Q3T.

FIG. 12A illustrates an exemplary schematic of a first RF circuit 1200 implemented in the bottom wafer 300 as described in reference to FIGS. 1 to 9. FIG. 12B illustrates an exemplary schematic of a second RF circuit 1202 implemented in the top wafer 400 as described in reference to FIGS. 1 to 9. All elements as shown in FIGS. 12A and 12B that were previously described in reference to FIGS. 1 to 11A and 11B will continue to have the same reference numerals as those discussed and are not described here for brevity. The first RF circuit 1200 and the second RF circuit 1202 as discussed in reference to FIGS. 12A and 12B are substantially similar to the first RF circuit 1100 and the second RF circuit 1102 as described in reference to FIGS. 11A and 11B with the exception that the resistors connected to gate, body, and source-drain nodes that were previously shown in FIG. 11A are removed from the second RF circuit 1202, and the first RF circuit 1200 and the second RF circuit 1202 form an asymmetric connection. The nodes RF_INPUT, RF_OUTPUT, VG, VB, SD0, SD1, SD2, SD3, G1, G2, G3, B1, B2, and B3 are all connected with one or more HB vias, such as HB vias 314, 412, which are aligned when the bottom wafer 300 and the top wafer 400 are bonded in accordance with the hybrid wafer bonding method described previously in FIGS. 1 to 9.

Asymmetric circuit may be an aspect because the FETs Q1T, Q2T, Q3T in the top wafer 400 may have a larger vertical distance to the silicon handle wafer 204 in the bottom wafer substrate 200 of the bottom wafer 400. This results in FETs Q1T, Q2T, Q3T having a greater thermal resistance in comparison to FETs Q1B, Q2B, and Q3B that form part of the bottom wafer 300. The first RF circuit 1200 may comprise gate, body, and source-drain resistors these elements RG1B, RG2B, RG3B, RB1B, RB2B, RB3B, RSD1B, RSD2B, and RSD3B that may have significant current density under RF operation. Therefore, absent a gate, body, and source-drain resistor in the second RF circuit 1202, the second RF circuit 1202 may take advantage of the greater bulk in the bottom wafer 300. Accordingly, using asymmetric RF circuit connections between the first RF circuit 1200 and the second RF circuit 1202 to take advantage of the difference in thermal performance may result in lower resistor temperature and ensure more reliable operation of the first RF circuit 1200 and the second RF circuit 1202 as coupled to one another.

FIG. 13A illustrates an exemplary first RF circuit 1300 implemented in the bottom wafer 300 as described in reference to FIGS. 1 to 9. FIG. 13B illustrates exemplary second RF circuit 1302 implemented in the top wafer 400 as described in reference to FIGS. 1 to 9. All elements as shown in FIGS. 13A and 13B that were previously described in reference to FIGS. 1 to 12A and 12B will continue to have the same reference numerals as those discussed and are not described here for brevity.

In this example, the first RF circuit 1300 and the second RF circuit 1302 as coupled to one another function as a switch comprising FETs Q1B, Q2B, Q3B, and Q4B in the bottom wafer 300 and Q1T, Q2T, Q3T, and Q4T in the top wafer 400. In addition, the resistors connected between gate nodes and body nodes of FETs Q1B, Q2B, Q3B, and Q4B and DC supplies VG and VB are connected in series, rather than in parallel. Common body resistor RBCOM and common gate resistor RGCOM are added between the DC supplies VG and VB and the gate and body resistors. In one aspect, the first RF circuit 1300 and the second RF circuit 1302 may have performance advantages based on this configuration of elements, such as improved insertion loss/isolation, linearity, and voltage handling. To minimize the FET self-heating, metal connections including an array of HB vias 314, 412 are located on the bottom wafer 300 and the top wafer 400 to provide a thermal pathway (with lower thermal resistance) for heat to flow from the FET source-drain nodes SD0, SD1, SD2, SD3, and SD4 in second RF circuit 1302 in the top wafer 202 to FET source-drain nodes SD0, SD1, SD2, SD3 in first RF circuit 1300 in the bottom wafer 300. This allows heat to flow from the transistors Q1T, Q2T, Q3T, and Q4T in the top wafer 400 to transistors Q1B, Q2B, Q3B, and Q4B in the bottom wafer 300. Heat in the bottom wafer 300 may then move through the silicon handle wafer 204 and eventually to the circuit board or package (not shown in FIGS. 13A and 13B).

FIG. 14 illustrates an exemplary layout 1400 of the RF switch 1000 shown in FIG. 10. The layout 1400 comprises the same elements as the RF switch 1000 of FIG. 10 and therefore, a description of such elements is not included for brevity. In this regard, the FETs Q1, Q2, and Q3 have a width W that corresponds to the gate width of each of the FETs Q1, Q2, and Q3. The gate resistors RG1, RG2, and RG3, the body resistors RB1, RB2, and RB3, and the source-drain resistors RSD1, RSD2, and RSD3 correspond to and are connected to the RF switch 1000 of FIG. 10. Furthermore, the source-drain nodes SD0, SD1, SD2, and SD3 between the FETs Q1, Q2, and Q3 of the RF circuit 1000 are shown in the form of metal connections in the layout 1400.

FIG. 15 shows exemplary layout for the first RF circuit 1200 and the second RF circuit 1202 as shown in FIG. 12. FIG. 16 is an alternative metallization arrangement of FIG. 15 to allow more HB vias. In this regard, FIGS. 15 and 16 show exemplary layouts side-by-side prior to bonding of the bottom wafer 300 and top wafer 400 as described in reference to FIGS. 1 to 9. The layouts are shown side by side for clarity, but they are stacked on top of each other during bonding of the bottom wafer 300 and top wafer 400. As noted above, in accordance with the hybrid wafer bonding method described herein, the layouts 1500, 1502 of FIGS. 15 and 1600, 1602 of FIG. 16 have opposing FET stacks Q1T, Q2T, and Q3T in the top wafer 400 to FET stacks Q1B, Q2B, and Q3B in the bottom wafer 300 that are connected by being connected together from bonding of the bottom wafer 300 and top wafer 400. Gate, body, and source-drain resistors RG1B, RG2B, RG3B, RB1B, RB2B, RB3B, RSD1B, RSD2B, and RSD3B are connected to the FETs in bottom wafer 300 as shown. Source-drain metal connections SD0, SD1, SD2, and SD3 are connected as shown.

In one aspect, the gate width of FETs Q1T, Q2T, and Q3T in the top wafer 400 to Q1B, Q2B, and Q3B in the bottom wafer 300 have a width (W) that is half of the width needed in the layout 1400 as shown in FIG. 14. This reduction in layout area is accomplished by duplicating the FETs Q1T, Q2T, and Q3T in the top wafer 400 to Q1B, Q2B, and Q3B in the bottom wafer 300, that allows each FET total channel width to be reduced by 50% and still maintain the same electrical performance as in layout 1400 of FIG. 14. Accordingly, this allows the die for RF products to be more compact/smaller.

It is to be noted that several HB vias, such as HB vias 314, 412 are also shown, which connect the bottom wafer 300 and top wafer 400. Metal connections with HB vias, such as HB vias 314, 412, covering a significant portion of the layout area are used to connect the source-drain nodes SD0, SD1, SD2, SD3 between the bottom wafer 300 and top wafer 400 to provide an enhanced thermal pathway, as described previously. Metal connections, such as HB vias, for example, HB vias 314 and 412, may be used to connect gate and body nodes G1, G2, G3, and B1, B2, and B3 of the FETs Q1T, Q2T, and Q3T in the top wafer 400 and FETs Q1B, Q2B, and Q3B together in bottom wafer 300. This provides the DC bias to the top wafer 400 FETs Q1, Q2, and Q3 through the gate and body resistors RG1B, RG2B, and RG3B, and RSD1B, RSD2B, and RSD3B, and RB1B, RB2B, and RB3B that are located on the bottom wafer 300.

FIG. 16 shows another exemplary layout 1600 for the first RF circuit 1200 and the second RF circuit 1202 as shown in FIG. 12 having an alternative metallization arrangement compared with FIG. 15 to allow for more HB vias. The RF switch area of the RF switch in layout 1600 can be reduced by nearly 50% using the disclosed hybrid wafer bonding process. In addition, a smaller RF switch area also reduces the coupling capacitance of the RF switch to its silicon handle wafer (not shown), since the top wafer 400 FETs Q1T, Q2T, and Q3T are relatively far from the silicon handle wafer. Lower coupling capacitance to the silicon handle wafer helps equalize RF voltage division across the top wafer 400 FETs Q1T, Q2T, and Q3T, resulting in improved RF voltage handling. Lower coupling capacitance to the silicon handle wafer may also improve the off-state RF isolation, due to lower parasitic capacitance between the RF_INPUT and the RF_OUTPUT. The smaller RF switch width can also improve the parasitic resistance for metal connections to the RF switch, improving on-state RF insertion loss, due to lower resistance between the RF_INPUT and the RF_OUTPUT.

FIG. 17 shows an exemplary cross-section image 1700 of the bottom wafer 300 and the top wafer 400 bonded together using the hybrid bonding process as shown in FIGS. 1 to 9. FIG. 17 is provided to show the layer structure and is not intended to indicate the circuit function. As shown, the top wafer 400 is flipped in orientation and bonded in an opposing manner to bottom wafer 300. This stacking of bottom wafer 300 and top wafer 400 enables a 3D structure that allows for increased density and functionality in a smaller 2D layout area. In particular, the cross-sectional image 1700 shows how the bottom wafer 300 and the top wafer 400 are folded over and bonded together to connect, for example, the transistors in the bottom wafer 300 with transistors in the top wafer 400. The bottom wafer 300 and the top wafer 400 are connected by being folded over each other vertically and provide electrical connections, for example, through HB vias 314, and 412.

FIG. 18A illustrates an exemplary RF circuit 1800 implemented on a single wafer supplemented with enhancement circuits 1808A to 1808F. It is important to note that RF circuit 1800 may include arrangements of resistors, FETs, capacitors, diodes, or other elements that are not shown here for simplicity. As shown, the RF circuit 1800 is similar to the RF switch 1000 as shown in FIG. 10. FIG. 18B is an exemplary RF circuit 1802 as previously discussed in reference to FIG. 10.

FIG. 19 is a diagram showing an exemplary layout 1900 of the RF circuit 1800 as shown in FIG. 18 as implemented in a single wafer. It is important to note that RF circuit 1800 may include arrangements of resistors, FETs, capacitors, diodes, or other elements that are not shown here for simplicity.

FIGS. 20A and 20B and 21A and 21B show respective RF circuits having opposing FET stacks, linearity improvement circuits, and voltage handling circuits that can be connected by being folded together in accordance with the hybrid wafer bonding process described herein. In particular, FIGS. 20A and 20B show an exemplary RF circuit 2000 having an RF switch 2002 with a stack of multiple FETS Q1T, Q2T, and Q3T implemented in the top wafer 400, while FIGS. 21A and 21B show an exemplary RF circuit 2100 implemented in the bottom wafer 300. In FIGS. 20A and 20B, RF circuit 2000 may comprise enhancement circuits 2006A-2006F similar to the enhancement circuits 1808A-1808F (shown in FIG. 18). As shown, enhancement section 2004 includes enhancement circuits 2006A-2006C that are linearity improvement circuits that may further include arrangements of resistors, FETs, capacitors, diodes. or other elements that are not shown here for simplicity and are placed between source-drain nodes SD0, SD1, SD2, and SD3. The enhancement circuits 2006A-2006C may comprise linearity improvement circuits and may further include arrangements of resistors, FETs, capacitors, diodes, or other elements that are not shown here for simplicity. Enhancement section 2004 may also include enhancement circuits 2006D-2006F that are voltage handling improvement circuits that may further include arrangements of resistors, FETs, capacitors, diodes, or other elements that are not shown here for simplicity and are placed between body nodes B1, B2, and B3 and adjacent source-drain nodes SD0, SD1, SD2, and SD3.

Referring now to FIGS. 21A and 21B, RF circuit 2100 is also similar to second RF circuit 1202 (shown in FIG. 12A) and comprises an RF switch 2102 having a stack of multiple FETS Q1B, Q2B, and Q3B. In addition, RF circuit 2100 in FIG. 21A may comprise enhancement section 2104 having enhancement circuits 2106A-2106F similar to the enhancement circuits 1808A-1808F (shown in FIG. 18). As shown, enhancement circuits 2106A-2106C may comprise linearity improvement circuits (not shown) placed between source-drain nodes SD0, SD1, SD2, and SD3 and may include arrangements of resistors, FETs, capacitors, diodes, or other elements. Enhancement circuits 2106D-2106F may comprise voltage handling improvement circuits (not shown) placed between body nodes B1, B2, and B3 and adjacent source-drain nodes SD0, SD1, SD2, SD3.

Since the enhancement circuits 2006A-2006F or 2106A-2106F (shown in FIGS. 20A and 21A, respectively) are mirrored versions placed respectively on the top wafer 400 and bottom wafer 300, and the size of these elements can be approximately 50% smaller in area of layout compared with enhancement circuit 1806 (shown in FIG. 18), which is implemented on a single wafer.

In this regard, FIG. 22A shows exemplary layout 2200 implemented in the bottom wafer 300. FIG. 22B shows exemplary layout 2202 implemented in the top wafer 400. Layout 2200 corresponds to the RF circuit 2100 shown in FIG. 21a. The layouts 2200, 2202 are shown side by side for clarity, but they are stacked on top of each other during bonding of the bottom wafer 300 and top wafer 400. All elements as shown in FIGS. 22A and 22B that were previously described in reference to FIGS. 1 to 21A and 21B will continue to have the same reference numerals as those discussed and are not described here for brevity.

As shown, the layouts 2200, 2202 have opposing FET stacks Q1T, Q2T, and Q3T in the top wafer 400 to Q1B, Q2B, and Q3B in the bottom wafer 300 that are connected by being folded together from bonding of the bottom wafer 300 and the top wafer 400. Gate, body, and source-drain resistors RG1B, RG2B, RG3B, RB1B, RB2B, RB3B, RSD1B, RSD2B, and RSD3B are connected to the FETs in bottom wafer 300 as shown. Source-drain metal connections SD0, SD1, SD2, SD3 are connected as shown as well. As noted previously, the gate width of FETs Q1T, Q2T, and Q3T in the top wafer 400 to Q1B, Q2B, and Q3B in the bottom wafer 300 may now have a width (W) half of the width needed in layout 1400 as shown in FIG. 14 for the total gate width of each FET.

Of note, several HB vias, such as HB vias 314, 412, are also shown, which connect the bottom wafer 300 and the top wafer 400. Metal connections with HB vias, such as HB vias 314, 412, covering a significant portion of the layout area are used to connect the SD0, SD1, SD2, SD3 nodes between the bottom wafer 300 and top wafer 400 to provide an enhanced thermal pathway, as described previously. Metal connections, such as HB vias 314, 412. can also be used to connect gate and body nodes G1, G2, and G3, and B1, B2, and B3 of the FETs Q1T, Q2T, and Q3T and FETs Q1B, Q2B, and Q3B together in bottom wafer 300. This provides the DC bias to the FETs Q1T, Q2T, and Q3T in top wafer 400 through the gate and body resistors RG1B, RG2B, RG3B, RB1B, RB2B, and RB3B that are located on the bottom wafer 300.

Furthermore, since the enhancement circuits 2106A-2106F are implemented in the bottom wafer 300 and the enhancement circuits 2006A-2006F are implemented in the top wafer 400, these circuits now consume less 2D area. Accordingly, even with enhancement circuits 2106A-2106F and 2006A-2006F, their layout is significantly less than a conventional single wafer implementation and enables a smaller die. Nevertheless, the linearity improvement circuits in enhancement circuits 2006A-2006C in the top wafer 400 and 2106A-2106C in the bottom wafer 300 may be around 30%, 40%, or 50% smaller because they have a width Y/2 that is approximately halved in comparison to the layout 1900 shown in FIG. 19. In addition, the voltage handling improvement circuits in enhancement circuits 2006D-2006F implemented in the top wafer 400 and 2106D-2106F in the bottom wafer 300 may have a size around 30%, 40%, or 50% smaller because they have a width X/2 that is approximately halved in comparison to the layout 1900 shown in FIG. 19.

FIG. 23A shows a side view of an exemplary and conventional RFSOI RF die 2300 diced from a single wafer. As shown, the RFSOI RF die 2300 comprises a control circuit 2302 having, for example, a digital logic interface, a switch bias voltage generator, a multiplexer, a switch driver, an electrostatic discharge protection, or the like, that are not shown here for brevity. The control circuit 2302 further comprises a voltage VDD supply terminal 2304 and a ground GND terminal 2306. In addition, the RFSOI RF die 2300 may comprise a first RF switch 2308 having a first and a second backside metal interconnects 2312 and 2314, respectively. Furthermore, the RFSOI RF die 2300 comprises a second RF switch 2310, having a third and a fourth backside metal interconnects 2316 and 2318, respectively. These elements are implemented on a single wafer prior to being diced into the RFSOI RF die 2300.

FIG. 23B shows a side view of an RF switch die 2320 having a bottom die portion 2322 and a top die portion 2324. The bottom die portion 2322 comprises a first bottom die RF switch 2328, a second bottom die RF switch 2326, and a bottom die control circuit 2336. The top die portion 2324 comprises a first top die RF switch 2332, a second top die RF switch 2330, and a top die control circuit 2334. In this manner, the first RF switch is divided into a top half 2332 and a bottom half 2328, the second RF switch is divided into a top half 2330 and a bottom half 2326, and the control circuit is divided into a top half 2334 and a bottom half 2336 based on the topologies and layouts described above with reference to FIGS. 11-22. This is particularly advantageous as it enables the RF switch die 2320 to have a die area that is 30%, 40%, or 50% smaller than the RFSOI RF die 2300 as shown in FIG. 23A.

FIG. 24A illustrates a layout area of an exemplary and conventional RFSOI RF switch die 2300. The RFSOI RF switch die 2300 comprises a control circuit 2302 having, for example, a digital logic interface, a switch bias voltage generator, a multiplexer, a switch driver, an electrostatic discharge protection, or the like, that are not shown here for brevity. The control circuit 2302 further comprises a voltage VDD supply terminal 2304 and a ground GND terminal 2306. In addition, the RFSOI RF die 2300 may comprise a first RF switch 2308 having a first and a second backside metal interconnects 2312 and 2314 respectively. Furthermore, the RFSOI RF die 2300 comprises a second RF switch 2310, having a third and a fourth backside metal interconnects 2316 and 2318, respectively. These elements are implemented on a single wafer prior to being diced into the RFSOI RF die 2300.

FIG. 24B shows a layout area of an exemplary RF switch die 2320. In this regard, the RF switch die 2320 is shown as seen after the bottom die 2320 and the top die 2324 (as shown in FIG. 23B) are bonded together, for example, using the process described with reference to FIGS. 1A-1G and FIGS. 2-9. Therefore, the top portions 2326, 2330, and 2334 are disposed above the bottom portions 2328, 2332, and 2336. This allows the RF switch die 2320 to have a significantly smaller 2D layout area compared with the RFSOI RF switch die 2300 (shown in FIG. 24A and FIG. 23A) due to a utilization of 3D stacking and folding. Therefore, the RF switch die 2320 may have a die area that is 30%, 40%, or 50% smaller than the RFSOI RF die 2300 as shown in FIG. 24A. In an embodiment, the RF switch die 2320 has a minimal height difference relative to the RFSOI RF die 2300, for example, using conventional thinning of the silicon handle wafer 204 in bottom wafer substrate 200 of the bottom wafer 300 (as shown in FIGS. 2A and 2B).

Accordingly, the 3D RFSOI hybrid wafer bonding method described herein and RF circuit schematics and layouts shown in FIGS. 11A-13B, 15 and 16, 20A-22B, 23B, and 24B can provide improved RF circuits and RF products that utilize less layout area, minimal to no change in height, and similar or improved performance. Such aspects may be useful in a variety of applications, such as switches and amplifiers for a user element device, e.g., a mobile wireless device.

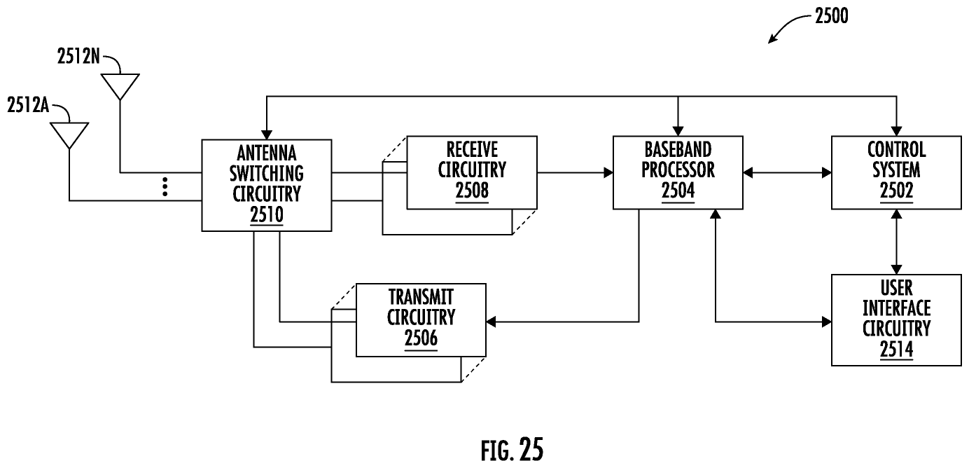

FIG. 25 shows an exemplary user element 2500 that includes the RF circuits including but not limited to the RF circuit schematics and layouts shown in FIGS. 11A-13B, 15 and 16, 20A-22B, 23B, and 24B. The RF circuits described above can operate as various devices, such as a switch, a power switch, amplifiers, filters, and frequency converters, which can be integrated in a user element, such as a communications device, mobile phone, and the like.

With continued reference to FIG. 25, the concepts described above may be implemented in various types of user elements 2500, such as mobile terminals, smart watches, tablets, computers, navigation devices, access points, and like wireless communication devices that support wireless communications, such as cellular, wireless local area network (WLAN), Bluetooth, and near-field communications. The user elements 2500 will generally include a control system 2502, a baseband processor 2504, transmit circuitry 2506, receive circuitry 2508, antenna switching circuitry 2510, multiple antennas 2512A-2512N, and user interface circuity 2514. In a non-limiting example, the control system 2502 can be a field-programmable gate array (FPGA) or an application-specific integrated circuit (ASIC). In this regard, the control system 2502 can include at least a microprocessor, an embedded memory circuit, and a communication bus interface. The receive circuitry 2508 receives radio frequency signals via the antennas 2512A-2512N and through the antenna switching circuitry 2510 from one or more base stations. A low-noise amplifier and a filter of the receive circuitry 2508 cooperate to amplify and remove broadband interference from the received signal for processing. Downconversion and digitization circuitry (not shown) will then downconvert the filtered, received signal to an intermediate or baseband frequency signal, which is then digitized into one or more digital streams using analog-to-digital converters (ADCs).

The baseband processor 2504 processes the digitized received signal to extract the information or data bits conveyed in the received signal. This processing typically comprises demodulation, decoding, and error correction operations. The baseband processor 2504 is generally implemented in one or more digital signal processors (DSPs) and ASICs.

For transmission, the baseband processor 2504 receives digitized data, which may represent voice, data, or control information, from the control system 2502, which it encodes for transmission. The encoded data is output to the transmit circuitry 2506, where a digital-to-analog converter (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission and deliver the modulated carrier signal to the antennas 2512A-2512N through the antenna switching circuitry 2510. The multiple antennas 2512A-2512N and the replicated transmit circuitry 2506 and receive circuitry 2508 may provide spatial diversity. Modulation and processing details will be understood by those skilled in the art.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A method of fabricating a radio frequency (RF) circuit, comprising:
providing a first silicon-on-insulator (SOI) wafer;
providing a second SOI wafer;
providing a first transistor on the first SOI wafer;
providing a second transistor on the second SOI wafer; and
bonding the second SOI wafer to the first SOI wafer to form a bonded wafer, wherein the second transistor opposes the first transistor.

2. The method of claim 1, wherein first SOI wafer comprises a first handle wafer and the second SOI wafer comprises a second handle wafer, and further comprising removing the second handle wafer.

3. The method of claim 2, further comprising
providing at least one handle wafer contact between the first transistor and the first handle wafer.

4. The method of claim 1, further comprising:
providing a first metal layer on the first SOI wafer;
forming first vias from the first metal layer that electrically connect to the first transistor;
providing a second metal layer on the second SOI wafer; and
forming second vias from the second metal layer that electrically connect to the second transistor.

5. The method of claim 4, wherein bonding the second SOI wafer to the first SOI wafer further comprises bonding the first vias with the second vias to electrically connect the first transistor to the second transistor.

6. The method of claim 4, further comprising:
forming third vias from the first metal layer that provide a first thermal dissipation path;
forming fourth vias from the second metal layer that provide a second thermal dissipation path; and
bonding the second SOI wafer to the first SOI wafer further comprises bonding the third vias with the fourth vias to thermally couple the first thermal dissipation path with the second thermal dissipation path.

7. The method of claim 1, further comprising forming a die from the bonded wafer comprising a first RF circuit from the first transistor and a second RF circuit from the second transistor, wherein the first RF circuit and the second RF circuit are electrically coupled.

8. A radio frequency (RF) circuit comprising:
a first RF circuit on a first layer of a substrate;
a second RF circuit on a second layer opposing the first layer; and
an interface layer between the first layer and the second layer and comprising at least one via electrically connected to the first RF circuit and the second RF circuit.

9. The RF product of claim 8, wherein the substrate further comprises an insulating layer between the first layer and the substrate.

10. The RF product of claim 8, wherein the first RF circuit mirrors the second RF circuit.

11. The RF product of claim 8, wherein:
the first RF circuit comprises a first field-effect transistor (FET) having a first drain, a first source, and a first gate; and
the second RF circuit comprises a second FET having a second drain, a second source, and a second gate.

12. The RF product of claim 11, wherein:
the first RF circuit further comprises a first resistor connected between a gate terminal and a gate voltage terminal, a second resistor connected between a first body terminal of the first FET and a body voltage terminal, and a third resistor connected between the first source and the first drain.

13. The RF product of claim 12, wherein:
the second RF circuit further comprises a fourth resistor connected between the gate terminal and the gate voltage terminal, a fifth resistor connected between a second body terminal of the second FET and the body voltage terminal, and a sixth resistor connected between the second source and the second drain.

14. The RF product of claim 12, wherein the first RF circuit further comprises a seventh resistor connected between the gate voltage terminal and the first resistor, and an eighth resistor connected between the body voltage terminal and the second resistor.

15. The RF product of claim 12, wherein the first source and the second source are electrically connected by the at least one via.

16. The RF product of claim 12, wherein the first drain and second drain are electrically connected by the at least one via.

17. The RF product of claim 12, wherein the first gate and the second gate are electrically connected by the at least one via.

18. The RF product of claim 12, wherein the second RF circuit further comprises at least one linearity improvement circuit electrically coupled to the first RF circuit by the at least one via.

19. The RF product of claim 12, wherein the second RF circuit further comprises at least one voltage handling improvement circuit electrically coupled to the first RF circuit by the at least one via.

20. The RF product of claim 12, wherein the second RF circuit further comprises at least one voltage handling improvement circuit and at least one linearity improvement circuit that are each electrically coupled to the first RF circuit by a respective one of the at least one via.
